(19) United States
(12) Patent Application Publication
(10) Pub. No.: US 2003/0192005 A1
(43) Pub. Date: Oct. 9, 2003

(54) Method and apparatus for error detection

(75) Inventors: Clifton James Williamson, Soquel, CA (US); Peter Igorevich Vasiliev, Cupertino, CA (US)

Correspondence Address: Merchant & Gould P.C., P.O. Box 2903, Minneapolis, MN, 55502-0903, US

(73) Assignee: Seagate Technology LLC

(21) Appl. No.: 10/390,996

(22) Filed: Mar. 17, 2003

Related U.S. Application Data
(60) Provisional application No. 60/370,352, filed on Apr. 5, 2002.

(51) Int. Cl. H03M 13/00; G11C 29/00

(52) U.S. Cl. 714/758

(57) ABSTRACT

The present invention is an error detection and correction scheme that enables the use of Horner's algorithm for the computation of EDC syndromes from the computed error pattern. Specifically, “transformed” EDC syndromes are computed during the read back of data and parity from the medium. The transformed syndromes are values of the polynomial whose coefficients occur in reverse order from that of the EDC codeword polynomial. In essence, by reversing the order of the coefficients, the Chien search processes the terms in descending order which is the right direction for Horner evaluation.

### RELATED APPLICATIONS

This application claims priority of U.S. provisional application Serial No. 60/370,352, filed Apr. 5, 2002.

### FIELD OF THE INVENTION

This application relates generally to data communication and/or storage, and more particularly to error detection.

### BACKGROUND OF THE INVENTION

In the field of digital data storage, data reliability is critical. Specifically, it is important that the user data that are retrieved from a medium match the data that were written to and stored on the medium. For a variety of reasons, the retrieved data may differ from the data that were originally stored. Any differences between the stored data and the retrieved data are considered errors in the data. Traditional methods for ensuring data reliability have included error detection and error correction. Typical error detection and correction techniques involve appending parity bits to the user data during an encoding process to form a code word prior to storage. When the code word (user data with parity bits) is later retrieved from the medium, it is decoded, whereby the parity bits are used to detect and correct errors. Essentially, the parity symbols provide redundancy, which may be used to check that the data were read correctly from the medium.

Digital data is typically partitioned into a number of symbols, each consisting of a fixed number of bits. For example, in the field of data storage, 8-bit symbols or “bytes” are commonly used. An h-bit symbol may be viewed as an element of the Galois Field GF(2^{h}), which is a finite field having unique mathematical properties. By treating the data as Galois field elements, mathematical operations may be performed on the symbols in a data storage device to reach useful results, including checking for errors. Error detection and correction algorithms, such as those used with the well-known Reed-Solomon (RS) codes, take advantage of the mathematical properties of Galois Fields. An error correction algorithm is able to correct up to a maximum number of symbol errors. The maximum number of symbol errors that the algorithm can correct is referred to as the “correction power” of the code. Error correction algorithms are able to correct errors primarily because a limited number of data blocks constitute the valid code words that may be stored on the medium.

Typically, before user data is stored, it is first encoded with parity symbols for the sole purpose of error detection. These parity symbols are computed from the user data and the block of data consisting of the user data and the parity symbols forms a code word in an error detection code (EDC). The parity symbols will be referred to as EDC parity and the block of data together with its EDC parity will be referred to as an EDC codeword. (For many classes of codes, such as the RS codes, the code symbols are viewed as elements of a Galois field and the code word is viewed as a polynomial whose coefficients are those Galois field elements. The defining property of the code is that certain values of these polynomials are equal to zero. These codes are called “polynomial codes”.)

In addition, the user data and EDC parity (EDC codeword) may be encoded with additional parity symbols for the purpose of error correction. These parity symbols are computed from the user data and EDC parity and the block of data consisting of the user data, the EDC parity, and the additional parity symbols form a code word in an error correction code (ECC). The additional parity symbols will be referred to as ECC parity. The entire block of data together with its EDC parity and ECC parity will be referred to as an ECC codeword. During decoding, while the erroneous data is retrieved, two sets of “syndromes”, one associated with the EDC and the other associated with the ECC, are computed. The two sets of syndromes are referred to as the EDC syndromes and the ECC syndromes. In the case of polynomial codes, these syndromes are the polynomial values used to define the codes, which are equal to zero when the data block constitutes a valid codeword. Thus, if the EDC syndromes are non-zero, i.e. if any bit in any syndrome is 1, an error has occurred in the EDC codeword. Similarly if the ECC syndromes are non-zero, an error has occurred in the ECC codeword. Furthermore, if an error is identified by the ECC syndromes, an error correction algorithm may then use the ECC syndromes to attempt to correct the error.

A typical error correction algorithm applies a minimum distance rule, in which a block of data containing errors (an “invalid” or “corrupted” codeword) is changed to the “closest” valid codeword. The “distance” between two blocks of data is the number of symbols in which the blocks differ, so that the closest codeword to a block of data is the codeword which differs from that block in as few symbols as possible. This is referred to as “maximum likelihood decoding” because an error event in which a small number of symbols are corrupted is generally more likely to occur than an event in which a large number of symbols are corrupted. However, in some cases, for example when massive data corruption occurs, the closest codeword to a corrupted codeword may not be the codeword originally written to the storage medium. In this instance, the algorithm will still “correct” the codeword to the closest valid codeword. Such a “miscorrection” results in an undetected corruption of user data. Clearly, a robust error control system must include mechanisms that guard against miscorrections. One such mechanism is contained in the error correction algorithm itself: generally when an error event beyond the correction power of a code occurs, then with high probability the algorithm will detect that the errors are uncorrectable. A second mechanism against miscorrection is the EDC. If the error correction algorithm has restored a corrupted codeword to the codeword originally written to the medium, then in particular the user data and EDC parity symbols have been restored. Thus, if the EDC syndromes are recomputed from the corrected data, they will all be zero. If a (possibly erroneous) correction has been performed and the recomputed EDC syndromes are not all zero, then the EDC has detected a miscorrection. In this way, the EDC reduces the likelihood of undetected data corruption even further.

Current approaches to decoding data involve implementations of Horner's algorithm, a key equation solver, a Chien search, and Forney's algorithm. Horner's algorithm is a method for evalutating polynomials and is used to compute the polynomial values that comprise the EDC and ECC syndromes. An error locator polynomial and an error evaluator polynomial are computed from the ECC syndromes by a key equation solver, such the Berlekamp-Massey algorithm. The roots of the error locator polynomial are Galois field elements, which correspond to locations of errors in the ECC codeword. The roots of the polynomial, and hence the locations of the errors, can be computed by a systematic search called a Chien search. Once an error location has been identified, the “error value” needed to correct the error can be computed by Forney's algorithm. It is desirable to use Horner's algorithm to recompute EDC syndromes after error correction has been performed, but current approaches have a number of drawbacks.

One approach is to store the corrupted user data and EDC parity symbols in a buffer, perform corrections on the data in the buffer, and then recompute the EDC syndromes as the corrected data are read from the buffer. In this case all the EDC syndromes should be zero. The drawback to this approach is the latency it adds to the system. Syndrome computation will not be complete until the last code symbol has been read from the buffer and at that point user data may already have been transferred to the host computer system. The host system must then be informed to disregard the data it has received. This is undesirable even though the storage device will most likely recover the data through a retry methodology such as rereading the data from the storage medium. To avoid additional system latency, it is desirable to recompute the EDC syndromes in parallel with the Chien search, so that the EDC will detect an ECC miscorrection before any user data have been transferred to the host. This approach is facilitated by the fact that the EDC syndromes can be computed from the error locations and values alone, instead of from the entire block of corrupted data. In this methodology, the EDC syndromes computed from the correction pattern are compared with the syndromes that were computed when the corrupted data were originally read from the medium. If the two sets of syndromes do not match, then the correction pattern does not match the actual error pattern and thus a mis-correction has been detected.

While it would be desirable to use Horner's algorithm to recompute the EDC syndromes from the error pattern, a difficulty arises from the order in which Horner's algorithm and the Chien search process codeword symbols. When a codeword is treated as a polynomial with Galois field coefficients, the coefficients of highest order are the first to be written to or read from the medium. This enables the use of Horner's algorithm, which processes the polynomial coefficients in descending order. However, the simplest implementation of a Chien search processes the locations corresponding to polynomial terms in ascending order, which is the “wrong direction” for Horner evaluation. The EDC syndromes can be computed from the error pattern by other methods, which require hardware more expensive than that for Horner evaluation.

It is with respect to these and other considerations that the present invention has been developed.

### SUMMARY OF THE INVENTION

One of the purposes of the present invention is to enable the use of Horner's algorithm for the computation of EDC syndromes from the computed error pattern. Specifically, “transformed” EDC syndromes are computed during the read back of data and parity from the medium. The transformed syndromes are values of the polynomial whose coefficients occur in reverse order from that of the EDC codeword polynomial. By reversing the order of the coefficients, the Chien search now processes the terms in descending order which is the right direction for Horner evaluation.

The present invention is described with specific reference to data storage on a magnetic medium. It is to be understood, however, that the present invention applies equally to data storage/retrieval from any type of medium for digital data storage and applies to data transmission or transfer systems and methods from one point to another with confirmation of data integrity, e.g., in which error detection and correction are needed.

These and various other features as well as advantages which characterize the present invention will be apparent from a reading of the following detailed description and a review of the associated drawings.

### BRIEF DESCRIPTION OF THE DRAWINGS

FIG. 1 is a plan view of a disc drive incorporating a preferred embodiment of the present invention showing the primary internal components.

FIG. 2 is a functional block diagram of the disc drive of FIG. 1 interacting with a host computer in accordance with a preferred embodiment of the present invention.

FIG. 3 illustrates an embodiment of a data transfer system that may be employed and the disc drive of FIG. 1.

FIG. 4 illustrates exemplary code words that may be transferred and analyzed for errors in an embodiment of the present invention.

FIG. 5 is a module diagram illustrating primary functional modules of a decoder of FIG. 3 in accordance with an embodiment of the present invention.

FIG. 6 illustrates one embodiment of a transformed error detection code (EDC) syndrome generator in accordance with the present invention.

FIG. 7 illustrates a circuit diagram in accordance with an embodiment of the EDC syndrome generator of FIG. 6.

FIG. 8 illustrates a circuit diagram in accordance with an embodiment of the EDC multiplier generator of FIG. 6.

FIG. 9 illustrates a circuit diagram in accordance with an embodiment of the error locator and transformed error generator of FIG. 5.

FIG. 10 illustrates a circuit diagram of an EDC syndrome computer in accordance with an alternative embodiment of the present invention.

FIG. 11 illustrates a circuit diagram of an EDC syndrome computer in accordance with another embodiment of the present invention.

FIG. 12 is an operation flow diagram illustrating exemplary operations employed by an embodiment of an error detection system.

FIG. 13 is an exemplary circuit for a polynomial code encoder.

FIG. 14 is an exemplary circuit for a concatenated encoding system in accordance with an embodiment of the present invention.

FIG. 15 illustrates exemplary code words that may be transferred and analyzed for errors in an embodiment of the present invention.

FIG. 16 is an exemplary circuit for computing polynomial values of \tilde{c}_{EDC}(x) and \tilde{c}_{ECC}(x) in accordance with an embodiment of the present invention.

### DETAILED DESCRIPTION

Embodiments of the present invention are described with reference to a series of figures. Generally, embodiments of the present invention relate to data transmission systems and methods and those systems and methods, for example, incorporated in a data storage device, such as a disc drive, for decoding data that are retrieved from a storage medium in the storage device. More particularly, embodiments relate to detecting errors in retrieved data to determine whether to correct the data and/or retrieve the data again. More particularly still, embodiments relate to performing error detection on data that has been corrected in parallel with identifying errors in the data. By validating ‘corrected’ data while retrieved data is being corrected, performance may be improved while the likelihood of passing incorrect data to a host computer is substantially reduced.

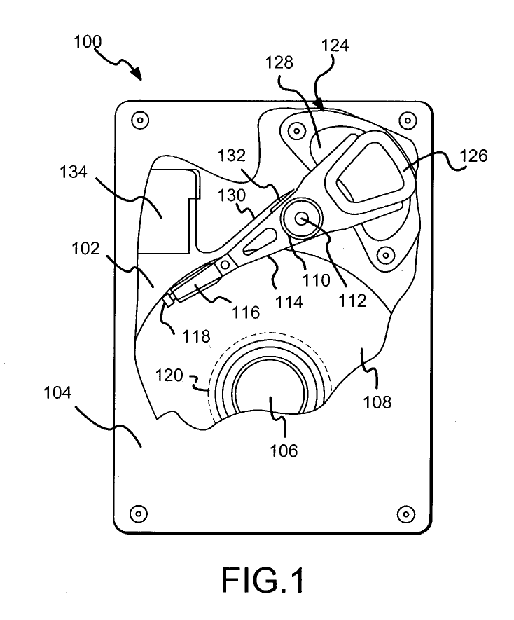

A disc drive 100 incorporating a preferred embodiment of the present invention is shown in FIG. 1. The disc drive 100 includes a baseplate 102 to which various components of the disc drive 100 are mounted. A top cover 104, shown partially cut away, cooperates with the baseplate 102 to form an internal, sealed environment for the disc drive in a conventional manner. The components include a spindle motor 106, which rotates one or more discs 108 at a constant high speed. Information is written to and read from tracks on the discs 108 through the use of an actuator assembly 110, which rotates during a seek operation about a bearing shaft assembly 112 positioned adjacent the discs 108. The actuator assembly 110 includes a plurality of actuator arms 114 which extend towards the discs 108, with one or more flexures 116 extending from each of the actuator arms 114. Mounted at the distal end of each of the flexures 116 is a read/write transducer head 118, which includes an air bearing slider enabling the head 118 to fly in close proximity above the corresponding surface of the associated disc 108.

During a seek operation, the track position of the heads 118 is controlled through the use of a voice coil motor (VCM) 124, which typically includes a coil 126 attached to the actuator assembly 110, as well as one or more permanent magnets 128 which establish a magnetic field in which the coil 126 is immersed. The controlled application of current to the coil 126 causes magnetic interaction between the permanent magnets 128 and the coil 126 so that the coil 126 moves in accordance with the well-known Lorentz relationship. As the coil 126 moves, the actuator assembly 110 pivots about the bearing shaft assembly 112, and the heads 118 are caused to move across the surfaces of the discs 108.

The spindle motor 106 is typically de-energized when the disc drive 100 is not in use for extended periods of time. The heads 118 are moved over park zones 120 near the inner diameter of the discs 108 when the drive motor is de-energized in this exemplary embodiment. The heads 118 are secured over the park zones 120 through the use of an actuator latch arrangement, which prevents inadvertent rotation of the actuator assembly 110 when the heads are parked.

A flex assembly 130 provides the requisite electrical connection paths for the actuator assembly 110 while allowing pivotal movement of the actuator assembly 110 during operation. The flex assembly includes a printed circuit board 132 to which head wires (not shown) are connected; the head wires being routed along the actuator arms 114 and the flexures 116 to the heads 118. The printed circuit board 132 typically includes circuitry for controlling the write currents applied to the heads 118 during a write operation and a preamplifier for amplifying read signals generated by the heads 118 during a read operation. The flex assembly terminates at a flex bracket 134 for communication through the baseplate 102 to a disc drive printed circuit board (not shown) mounted to the bottom side of the disc drive 100.

In the exemplary embodiment shown in FIG. 1, the write portion of the transducer head 118 in combination with current-controlling circuitry may generally be referred to as a communication module for communicating data onto the disc 108. The read portion of the transducer head 118 in combination with the preamplifier may be referred to as a retrieving module, whereby data is retrieved from the disc 108. In general, a communication module includes any hardware, software, and/or firmware operable to communicate data via or to a medium. Likewise, in general, a retrieving module includes any hardware, software, and/or firmware operable to receive data from the media. While embodiments described herein are directed at use in a disc drive, it is to be understood that other types of media, such as communications channels, and devices, such as transmitters and receivers, may advantageously employ embodiments of the present invention.

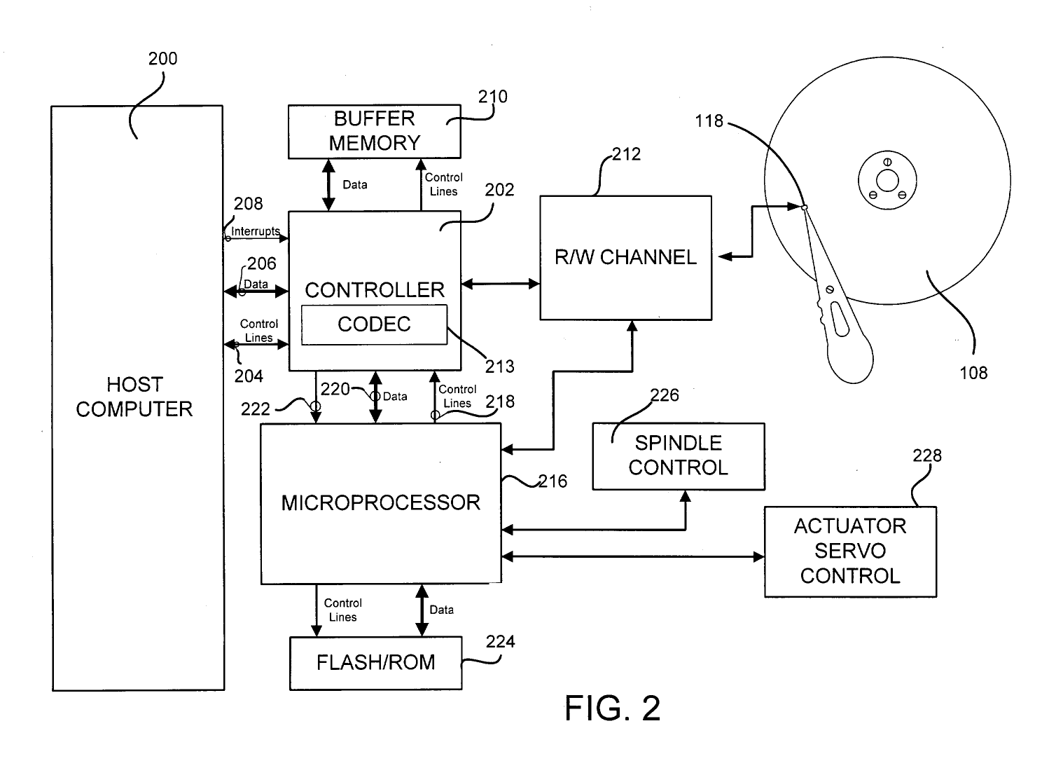

Referring now to FIG. 2, shown therein is a functional block diagram of the disc drive 100 of FIG. 1, generally showing the main functional circuits which are typically resident on a disc drive printed circuit board and which are used to control the operation of the disc drive 100. As shown in FIG. 2, the host 200 is operably connected to a controller ASIC (application specific integrated circuit) 202 via control lines 204, data lines 206, and interrupt lines 208. The controller 202 typically includes an associated buffer 210, which facilitates high-speed data transfer between the host 200 and the disc drive 100. Data to be written to the disc drive 100 are passed from the host to the controller 202 and then to a read/write channel 212, which encodes and serializes the data.

The controller 202 includes a coder/decoder (CODEC) 213 for encoding and decoding data. The CODEC 213 employs unique systems and methods for ensuring data reliability and timing recovery for a given code rate. Embodiments of the CODEC 213 are described with reference to functional block diagrams and operation flow diagrams in more detail below.

The read/write channel 212 also provides the requisite write current signals to the heads 118. To retrieve data that have been previously stored by the disc drive 100, read signals are generated by the heads 118 and provided to the read/write channel 212, which processes and outputs the retrieved data to the controller 202 for subsequent transfer to the host 200. Such operations of the disc drive 100 are well known in the art and are discussed, for example, in U.S. Pat. No. 5,276,662 issued Jan. 4, 1994 to Shaver et al.

As also shown in FIG. 2, a microprocessor 216 is operably connected to the controller 202 via control lines 218, data lines 220, and interrupt lines 222. The microprocessor 216 provides top level communication and control for the disc drive 100 in conjunction with programming for the microprocessor 216 which is typically stored in a microprocessor memory (MEM) 224. The MEM 224 can include random access memory (RAM), read only memory (ROM) and other sources of resident memory for the microprocessor 216. Additionally, the microprocessor 216 provides control signals for spindle control 226, and servo control 228.

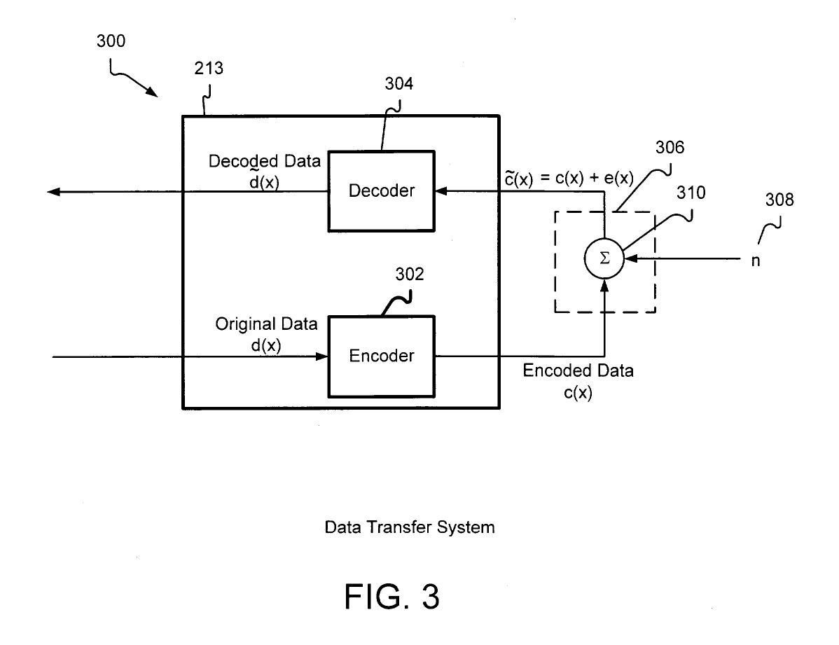

A data transfer system 300 in accordance with the invention is illustrated in FIG. 3. The data transfer system 300 includes one embodiment of the CODEC 213 (FIG. 2) in combination with a data transfer medium 306. In this particular embodiment, the CODEC 213 includes an encoder 302, and a decoder 304, which encode and decode data respectively. The encoder 302 receives input data, d(x), and outputs encoded data, c(x). The encoded data, c(x), is communicated via a data transfer medium 306. The data transfer medium 306 may be any communication channel, storage medium, or any other data transfer mechanism as may be known in the art. For example, the data transfer medium 306 may be a magnetic disc such as the disc 108 of FIG. 1.

One characteristic of the data transfer medium 306 is the existence of noise or other disturbance that may impart errors in the encoded data, c(x). Noise as used herein refers to any phenomenon, random, deterministic, or otherwise, which is associated with the transfer of data from the medium 306, and which tends to cause information (e.g., bits) in the encoded data to change. Thus, data transfer from/to the medium 306 imparts noise 308 upon the encoded data, c(x). In the diagram shown in FIG. 3, the medium 306 is abstracted as including an addition function 310, whereby the noise 308 is added to the encoded data, c(x). It is to be understood, however, that in general, noise can have other effects upon c(x) besides, or in combination with, additive effects.

Noise may be imparted on data in the disc drive 100 at any point along the data path. By way of example, and not limitation, the data transfer medium 306 in the disc drive 100 may include the disc 108 shown in FIG. 2. The data transfer medium 306 may further include the read/write channel 212 and the read/write head 118. After data are written to the disc 108, disturbances in the disc drive 100 may cause errors to arise in the data stored on the disc 108. Additionally, noise 308 may cause errors to arise in data as the data are being read from the disc 108. Thus, noise 308 may be imparted upon data when the data are in the read/write channel 212 before or after the data are written to the disc 108.

Errors resulting from noise as the data are read from the medium are often called read errors and may be detected using an embodiment of the present invention. Once detected, the read errors may be corrected or, if it is not possible to correct the read errors, the data may be retrieved again from the disc through retry operations. In an embodiment where the data transfer medium 306 is a data disc 108, a number of factors may contribute to the noise 308. For example, the head (e.g., the head 118 of FIG. 1) may not be centered on the center of the data track from which data are being read. When the head 118 is not centered properly, data may not be read properly. Often, if read errors occur because of improper head position, the head may be repositioned to be more in line with the track center to improve data reading. Many other conditions (besides head mispositioning) may arise in a disc drive, which may cause data to be improperly read from the disc.

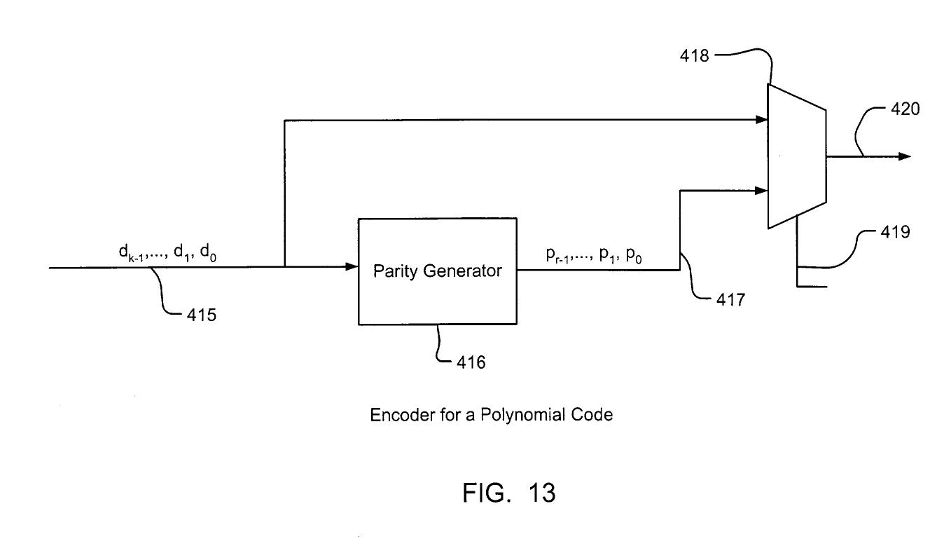

FIG. 13 illustrates a hardware implementation of a standard encoder for a systematic polynomial code, which is well understood by someone skilled in the art. The user data to be encoded 415 are partitioned into k data symbols dₖ₋₁, dₖ₋₂, . . . , d₁, d₀. Each symbol consists of h bits and is viewed as an element of the Galois field GF(2^{h}). The user data 415 are the inputs to a parity generator 416, which reads one symbol per clock cycle starting with dₖ₋₁ and ending with d₀, so that the transfer of the data symbols lasts k clock cycles. The outputs 417 of the parity generator 416 are partitioned into r parity symbols pᵣ₋₁, pᵣ₋₂, . . . , p₁, p_{0,}. Again each symbol consists of h bits and is viewed as an element of the Galois field GF(2^{h}). The parity symbols 417 are transferred from the parity generator 416 one symbol per clock starting with pᵣ₋₁ and ending with p₀. The transfer of the parity symbols 417 begins immediately after the last data symbol d₀ has been transferred and lasts r clock cycles. The data symbols 415 and the parity symbols 417 are the inputs to a multiplexer 418. When the user data symbols 415 are read by the parity generator 416, they also pass through the multiplexer 418 and are the outputs 420 of the encoder block. When the parity symbols 417 are transferred from the parity generator 416, then they pass through the multiplexer 418 and are the outputs 420 of the encoder block. During the first k clock cycles of the transfer, a control signal 419 determines that the outputs 420 are user data symbols. During the next r clock cycles, the control signal 419 determines that the outputs 420 are parity symbols. In this way, the outputs 420 constitute a codeword, whose transfer takes k+r clock cycles. The outputs 420 of the encoder block are written to a storage medium or may be inputs to another block in the error control system.

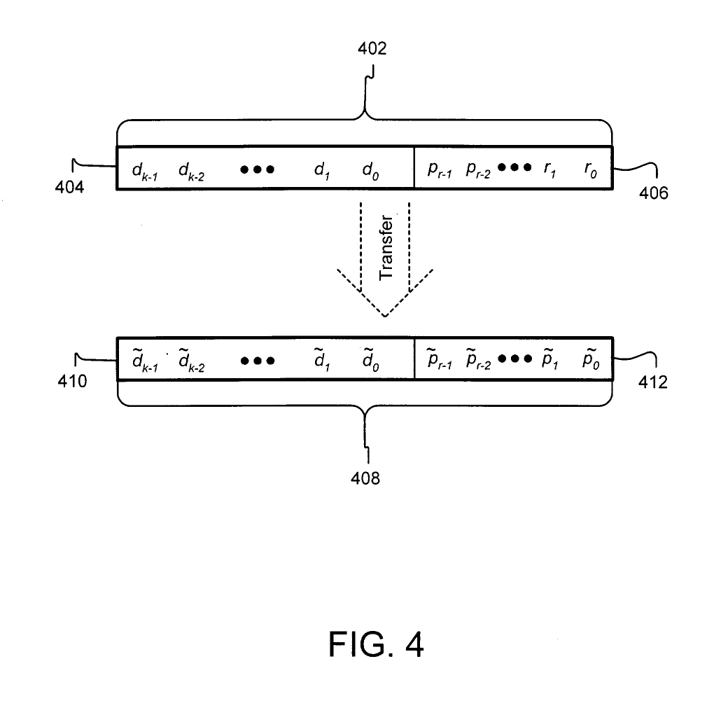

FIG. 4 illustrates the case where the data and parity symbols are transferred to the medium (e.g., storage medium or communication medium), in the form of an original codeword 402. The original codeword 402 is made up of two portions. The first portion 404 consists of user data. The user data are the series of data symbols, dₖ₋₁, dₖ₋₂, and so on. The second portion 406 includes parity symbols pᵣ₋₁, pᵣ₋₂, and so on.

The original codeword 402 is transferred to a medium, such as a magnetic disc. The original codeword 402 is later retrieved from the medium and decoded to detect any errors. After the original codeword 402 is retrieved, it is represented as a retrieved codeword 408. The retrieved code word 408 may differ from the original codeword 402 because read errors or other errors may arise. The retrieved codeword 408 is made up of retrieved user data 410 and retrieved parity data 412. The retrieved user data 410 include retrieved user symbols, \tilde{d}ₖ₋₁, \tilde{d}ₖ₋₂, and so on. The retrieved parity data 412 include retrieved parity symbols \tilde{p}ᵣ₋₁, \tilde{p}ᵣ₋₂, and so on. The retrieved parity data 412 are used to detect errors in symbols of the retrieved codeword 408.

As is shown in more detail below, the retrieved symbols of the retrieved user data 410 and the retrieved parity data 412 are used to calculate syndromes. The values of the syndromes indicate whether any bits in the retrieved code word 408 differ from the code word 402, and hence whether errors have arisen in the retrieved code word 408.

Referring to FIG. 3 and FIG. 4 together, the decoder 304 retrieves the transferred encoded data \tilde{c}(x) 408 from the channel 306 as it may have been changed by the medium and/or misread. The decoder 304 uses the retrieved parity data \tilde{p}(x) 412 to determine the user data d(x) 404 from the retrieved codeword \tilde{c}(x) 408. The retrieved parity \tilde{p}(x) 412 is the original parity p(x) including any changes to p(x) due to the channel 306 or a misread. The output of the decoder 304 is \tilde{d}(x) 410, which may differ from d(x) 404 if uncorrectable errors were imparted on c(x) 402 as it was transferred over the medium 306 and/or retrieved from the medium 306. The decoder 304 is designed to be able to correct up to a specified number of errors; however, if more errors occur than the specified number, then the decoder 304 may not be able to derive d(x) 404, but rather \tilde{d}(x) 410. As such, \tilde{d}(x) 410 may differ from d(x) 404.

Transferred data, such as the data illustrated in FIG. 4, may be represented as a polynomial. This polynomial is generally a summation of products of elements from a Galois field GF(2^{h}) with a power of a variable x. The polynomial representation will assist the reader in understanding the significant utility of embodiments of the present invention. Thus, user data d(x) 404 may be represented as a “data polynomial” as shown in equation (1) below.

d(x)=dₖ₋₁x^{k-1}+dₖ₋₂x^{k-2}+ . . . +d₂x²+d₁x¹+d₀ (1)

In general, d(x) 404 represents a series of symbols represented by the coefficients, dᵢ. Each coefficient, dᵢ represents the i^{th} symbol in d(x) 404, and a power xⁱ of a variable x holds the place of each coefficient, dᵢ, according to the order of the coefficient in the data block. The coefficient dₖ₋₁ is the first symbol in the block and d₀ is the last.

Likewise, the original parity p(x) 406 may be represented as a “parity polynomial” as shown in equation (2) below:

p(x)=pᵣ₋₁x^{r-1}+pᵣ₋₂x^{r-2} + . . . +p₂x²+p¹+p₀, (2)

where r parity symbols pi are computed based on the user data d(x) 404 and the particular encoding algorithm being used. During encoding, the r parity symbols pᵢ are appended to the data d(x) 404 to create the original codeword c(x) 402. The data, d(x), is input into the encoder 404 for error detection/correction encoding. The encoder calculates parity symbols and appends the symbols onto the data block d(x). The output of the ECC encoder is an encoded data block c(x). For example, the encoder 404 may employ a Reed-Solomon (RS) encoding algorithm.

The original codeword c(x) 402 can similarly be represented as a “codeword polynomial” as shown in equation (3) below:

c(x)=d(x)x^{r}+p(x)=dₖ₋₁x^{r+k-1}+ . . . d₀x^{r-1}+ . . . +p₀. (3)

During encoding, the parity symbols pᵢ are chosen so that the polynomial value c(a)=0, for all a in a certain subset A. The subset A typically has r elements in a Galois field, which may be GF(2^{h}), wherein h is the number of bits per symbol, or another Galois field containing GF(2^{h}). The symbols pᵢ may be generated in any manner consistent with the error detection/correction algorithm being used in a particular implementation. The particular manner in which the symbols pᵢ are calculated is not particularly relevant to an embodiment of the present invention. Thus, the particular steps, operations, and systems involved in generating the symbols rᵢ are not discussed in detail herein. Those skilled in the art are referred to “Error-Correction Coding for Digital Communications,” by Clark and Cain, for a more detailed discussion of parity symbol generation.

After the data are retrieved from the medium 306, it is assumed that errors may have been imparted on the code word c(x). Errors are represented by e(x) and are assumed to be added to the code word c(x). Thus, the retrieved data \tilde{c}(x) may be represented mathematically by Equation (4) below:

\tilde{c}(x)=c(x)+e(x). (4)

It will be appreciated that, by design, the value c(a) is equal to zero. Thus, the following is true:

\tilde{c}(a)=e(a). (5)

The respective data retrieved in the data transfer system may be represented in polynomial form as shown in Equations (6), (7), and (8).

\tilde{d}(x)=\tilde{d}ₖ₋₁x+^{k-1}+\tilde{d}ₖ₋₂x^{k-2}+ . . . +\tilde{d}₂x²+\tilde{d}₁x¹⁺\tilde{d}₀, (6)

\tilde{p}(x)=\tilde{p}ᵣ₋₁x^{r-1}+\tilde{p}ᵣ₋₂x^{r-2}+ . . . +\tilde{p}₂x²+\tilde{p}₁x¹+\tilde{p}₀, (7)

\tilde{c}(x)=\tilde{d}ᵣ₋₁x^{r+k-1}+ . . . \tilde{d}₀x^{r}+\tilde{p}ᵣ₋₁x^{r-1}+ . . . + [symbol] ₀, (8)

where \tilde{d}(x) is the retrieved user data, which may have errors; \tilde{p}(x) is the retrieved parity, which may have errors; and \tilde{c}(x) is the retrieved code word.

In embodiments described herein, the logical operations of the encoder 302 and the decoder 304 may be implemented as a sequence of computer implemented steps or program modules running on a microprocessor, such as, without limitation, a processor in a personal computer, computer workstation, or a disc drive (e.g., disc drive 100). It will be understood to those skilled in the art that the encoder 302 and the decoder 304 of the present invention may also be implemented as interconnected machine logic circuits or circuit modules within a computing system. The implementation is a matter of choice dependent on the performance requirements of the computing system implementing the encoder 302 and the decoder 304.

The operations, structural devices, acts, and/or modules described herein may be implemented in software, in firmware, in special purpose digital logic, and/or any combination thereof without deviating from the spirit and scope of the present invention as recited within the claims attached hereto. Furthermore, the various software routines or software modules described herein may be implemented by any means known in the art. For example, any number of computer programming languages, such as “C”, “C++”, Pascal, FORTRAN, assembly language, Java, etc., may be used. By way of further example, and not limitation, any scripting language known in the art may be used, such as Korn shell script. Furthermore, various programming approaches such as procedural, object oriented or artificial intelligence techniques may be employed.

The encoder 302 and the decoder 304 may be implemented as software modules executed by a disc drive, such as the disc drive 100 illustrated in FIG. 1. As described in greater detail below, the encoder 302 may be employed to receive, store, convert, encode, and/or communicate digital data. The encoder 302 employs microprocessor readable media for carrying out the various tasks associated with encoding data and communicating the data to be retrieved and decoded by the decoder 304. Similarly the decoder 304 employs microprocessor readable media for carrying out the various tasks associated with retrieving and decoding the data.

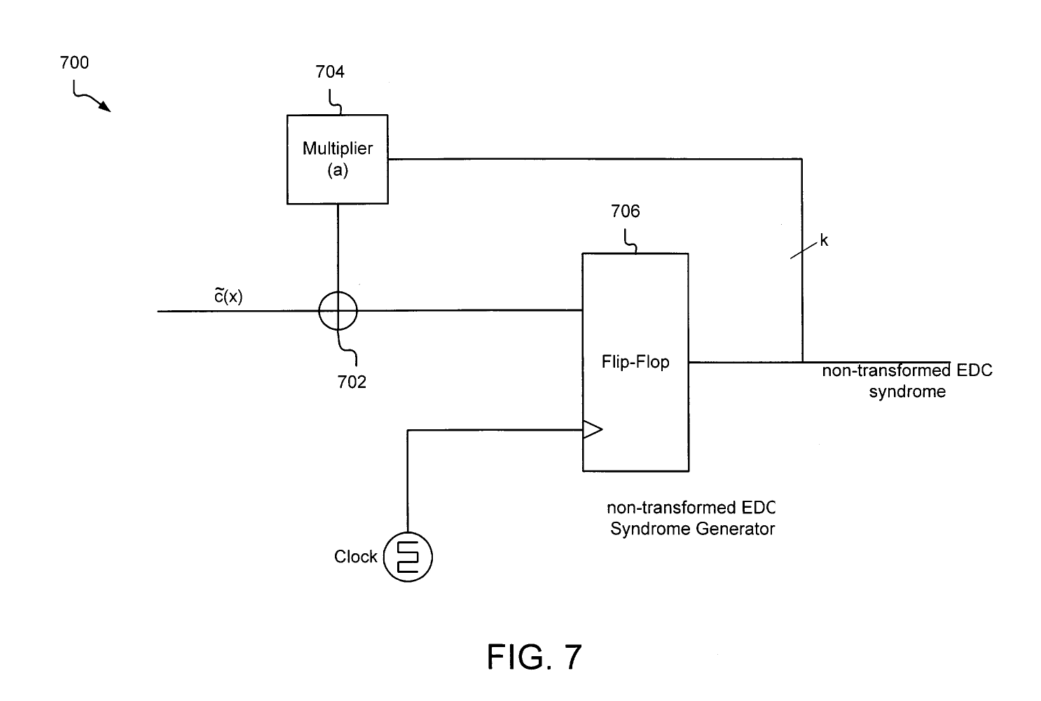

FIG. 7 illustrates a circuit 700 for computing the polynomial value \tilde{c}(a) in the case where the elements of A are in the Galois field GF(2^{h}). Several such circuits are required, one for each value a in A. The circuit 700 includes an adder module 702, a multiplier 704, and a bank of h flip-flops 706 (one of which is shown) generally coupled together in a feedback arrangement as shown. In general, the circuit 700 evaluates the retrieved code word \tilde{c}(x) at a fixed value a to yield a syndrome. The circuit 700 implements Horner's algorithm. As will be readily recognized, Horner's algorithm may be implemented with relatively simple, low-cost circuitry.

The retrieved code word \tilde{c}(x) is input to an adder module 702. The adder module 702 typically includes a series of XOR gates that add the symbols in \tilde{c}(x) to output from the multiplier 704. The Galois field coefficients of the retrieved code word \tilde{c}(x) are preferably clocked into the circuit 700, and data are subsequently clocked through the circuit 700. In one embodiment of the adder module 702, exclusive ‘or’ operations are performed on the data input to the adder module. The output of the adder module 702 is clocked into the bank of flip-flops 706.

The flip-flops 706 are generally memory registers that include a bank of bits that alternate between states. It is to be understood that other types of hardware are known in the art that could be used instead of, or in combination with, the flip-flops 706. The flip-flops 706 are initialized to zero before the transfer of \tilde{c}(x). The inputs to the flip-flops 706 are sequentially clocked in to the bank of bits and clocked out on a ‘first-in-first-out’ basis. The output of the flip-flops 706 includes an h-bit symbol that is fed into the multiplier 704.

The multiplier 704 multiplies the h-bit symbol from the flip-flops by a fixed value, a. The multiplier 704 may include any combinational logic, or software to perform the multiplication. By way of example, and not limitation, the multiplier 704 may be implemented in a microprocessor. Other, less expensive hardware, such as off-the-shelf integrated logic circuits may be used for the multiplier 704. Those skilled in the art will recognize other types of hardware, firmware, or software readily suited to implement the multiplier 704. The output of the multiplier 704 is clocked into the adder module 702.

The circuit 700 iteratively multiplies and sums symbols of \tilde{c}(x) to generate the a syndrome. The output of the circuit 700 may be viewed as an evaluation of the equation (8) wherein x is set equal to the fixed value a. Because a set of fixed values a is employed in the error detection algorithm, an embodiment of a decoder may include a plurality of circuits 700 wherein each circuit employs one of the fixed values, a. As such, as the retrieved code word \tilde{c}(x) is read from a medium (e.g., the disc 108 of FIG. 1), each symbol (coefficient) of \tilde{c}(x) may be multiplexed into the circuits, one coefficient per clock cycle. Before syndrome computation begins, the value in the flip-flops 706 represents the zero element in GF(2^{h}). As each coefficient of \tilde{c}(x) is clocked into the circuit, the value in the flip-flops 706 becomes the previous value stored in the flip-flops 706 multiplied by a plus the value of the coefficient. Thus, when the first coefficient \tilde{d}ₖ₋₁ is clocked into the circuit, the value in the flip-flops 706 becomes 0·α+\tilde{d}ₖ₋₁=\tilde{d}ₖ₋₁. When the second coefficient \tilde{d}ₖ₋₂ is clocked into the circuit, the value in the flip-flops 706 becomes \tilde{d}ₖ₋₁·α+\tilde{d}ₖ₋₂. When the third coefficient \tilde{d}ₖ₋₃ is clocked into the circuit, the value in the flip-flops 706 becomes (\tilde{d}ₖ₋₁·α+\tilde{d}ₖ₋₂)·α+\tilde{d}ₖ₋₃=\tilde{d}ₖ₋₁·α+\tilde{d}ₖ₋₃. When the last coefficient \tilde{p}₀ is clocked into the circuit, the value in the flip-flops 706 becomes \tilde{c}(α)=\tilde{d}ₖ₋₁α^{r+k-1}+ . . . +\tilde{d}₀α^{r-1}+ . . . + [symbol] ₀. The computation of the syndrome is complete after the last coefficient has been clocked into the circuit.

Preferred embodiments of the present invention involve a concatenated error control system in which there are two separate codes, an EDC (error detection code) and an ECC (error correction code). User data are first encoded with “EDC parity”, then with “ECC parity” and in each case the encoder is of the type described in FIG. 13. Specifically, the user data 415 again consist of k code symbols dₖ₋₁, dₖ₋₂, . . . , d₁, d₀ each consisting of h bits, which may be viewed as the coefficients of a data polynomial d(x) as in equation (1). The EDC parity generator 416 computes r parity symbols 417 pᵣ₋₁, pᵣ₋₂, . . . , p₁, p₀ which may be viewed as the coefficients of a parity polynomial p(x) as in equation (2). The codeword polynomial c(x) in equation (3) will be written as c_{EDC}(x) in equation (9) to emphasize that it is a codeword in the sense of the error detection code. Thus,

c_{EDC}(x)=d(x)x^{r}+p(x)=dₖ₋₁x^{r+k-1}+ . . . +d₀x^{r}+pᵣ₋₁x^{r-1}+ . . . +p₀. (9)

The polynomial c_{EDC}(x) plays the role of the data polynomial d(x) for the ECC parity generator, so that the r+k symbols dₖ₋₁, dₖ₋₂, . . . , d₁, d₀, pᵣ₋₁, pᵣ₋₂, . . . , p₁, p₀ are the inputs to the ECC parity generator. The ECC parity generator computes s parity symbols qₛ₋₁, qₛ₋₂, . . . , q₁, q₀ which may be viewed as the coefficients of a parity polynomial q(x) as in equation (10):

q(x)=qₛ₋₁x^{s-1}+qᵣ₋₂x^{s-2}+ . . . +q₂x²+q₁x¹+q₀, (10)

The parity symbols qₛ₋₁, qₛ₋₂, . . . , q₁, q₀ are appended to the symbols dₖ₋₁, dₖ₋₂, . . . , d₁, d₀, pᵣ₋₁, pᵣ₋₂, . . . , p₁, p₀ to create an ECC codeword, which may be viewed as a codeword polynomial c_{ECC(x)} as in equation (11):

c_{ECC}(x)=c_{EDC}(x)x^{s}+q(x)=dₖ₋₁x^{r+s+k-1}+ . . . +d₀x^{r+s}+pᵣ₋₁x^{r+s-1}+ . . . p₀x^{s}+qₛ₋₁x^{s-1}+ . . . +q₀. (11)

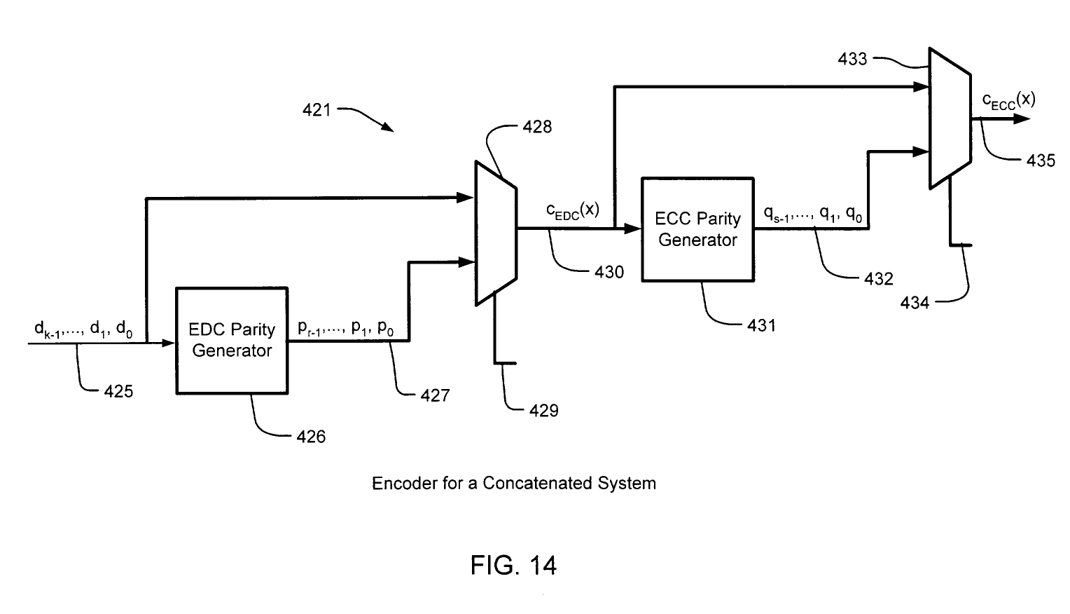

FIG. 14 illustrates a circuit 421 for the concatenated encoding system. The user data to be encoded 425 are partitioned into k data h-bit symbols dₖ₋₁, dₖ₋₂, . . . , d₁, d₀. The user data 425 are the inputs to an EDC parity generator 426, which reads one symbol per clock cycle starting with dₖ₋₁ and ending with d₀. The outputs 427 of the parity generator 426 are r h-bit EDC parity symbols pᵣ₋₁, pᵣ₋₂, . . . , p₁, p₀. After d₀ has been read, the parity symbols 427 are transferred from the EDC parity generator 426 one symbol per clock starting with pᵣ₋₁ and ending with p₀. The data symbols 425 and the EDC parity symbols 427 are the inputs to a multiplexor 428. The multiplexor is controlled by a signal 429, so that the outputs 430 of the multiplexor are data symbols during the first k clock cycles of the transfer and are EDC parity symbols during the next r clock cycles. The outputs 430 constitute an EDC codeword and are the inputs to the ECC parity generator 431. The inputs dₖ₋₁, dₖ₋₂, . . . , d₁, d₀, pᵣ₋₁, pᵣ₋₂, . . . , p₁, p₀ are read by the ECC parity generator 431 one symbol per clock cycle starting with dₖ₋₁ and ending with p₀. After p₀ has been read, the parity symbols 432 are transferred from the ECC parity generator 431 one symbol per clock starting with qₛ₋₁ and ending with q₀. The EDC codeword symbols 430 and the ECC parity symbols 432 are the inputs to a multiplexer 433. The multiplexer is controlled by a signal 434, so that the outputs 435 of the multiplexor are EDC codeword symbols during the first r+k clock cycles of the transfer and are ECC parity symbols during the next s clock cycles. The outputs 435 constitute an ECC codeword and are the outputs of the encoder block.

The EDC parity symbols pᵢ are chosen so that the polynomial value c_{EDC}(a)=0, for all a in a certain subset A. The subset A typically has r elements in a Galois field. The ECC parity symbols qⱼ are chosen so that the polynomial value c_{ECC}(b)=0, for all b in a certain subset B. The subset B typically has s elements in a Galois field. The symbols pᵢ and qⱼ may be generated in any manner consistent with the error detection/correction algorithm being used in a particular implementation. The particular manner in which the symbols pᵢ and qⱼ are calculated is not particularly relevant to an embodiment of the present invention.

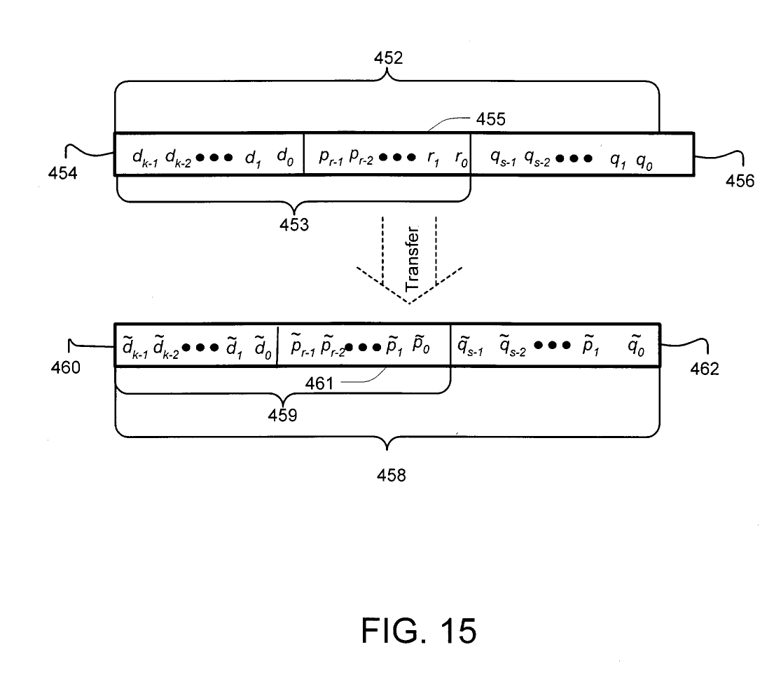

FIG. 15 illustrates the case where the data, EDC parity, and ECC parity symbols are transferred to the medium (e.g., storage medium or communication medium), in the form of an original ECC codeword 452. The original ECC codeword 452 is made up of three portions. The first portion 454 consists of user data. The user data are the series of data symbols, dₖ₋₁, dₖ₋₂, and so on. The second portion 455 includes EDC parity symbols pᵣ₋₁, pᵣ₋₂, and so on. The third portion 456 includes ECC parity symbols qₛ₋₁, qₛ₋₂, and so on. The original EDC codeword 453 is made up of user data 454 and EDC parity 455.

The original ECC codeword 452 is transferred to a storage medium, such as a magnetic disc. The original ECC codeword 452 is later retrieved from the medium and decoded to detect any errors. After the original ECC codeword 452 is retrieved, it is represented as a retrieved ECC codeword 458. The retrieved ECC codeword 458 may differ from the original codeword 452 because read errors or other errors may arise. The retrieved codeword 458 is made up of retrieved user data 460, retrieved EDC parity data 461, and retrieved ECC parity data 462. Similarly, the retrieved EDC codeword 459 is made up of retrieved user data 460 and retrieved EDC parity 461. The retrieved user data 460 include retrieved user symbols, \tilde{d}ₖ₋₁, \tilde{d}ₖ₋₂, and so on. The retrieved EDC parity data 461 include retrieved parity symbols \tilde{p}ᵣ₋₁, \tilde{p}ᵣ₋₂, and so on. The retrieved ECC parity data 462 include retrieved parity symbols \tilde{q}ₛ₋₁, \tilde{q}ₛ₋₂, and so on. The retrieved EDC parity data 461 and retrieved ECC parity data 462 are used to detect errors in symbols of the retrieved ECC codeword 458.

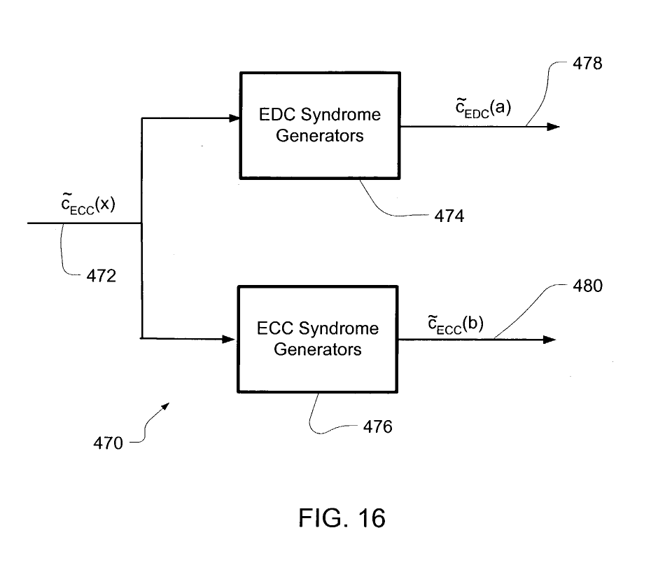

FIG. 16 illustrates a circuit 470 for computing the polynomial values \tilde{c}_{EDC}(a) and \tilde{c}_{ECC}(b), as a ranges over the set A and b ranges over the set B. The symbols in the retrieved codeword \tilde{c}_{ECC}(x) are the inputs 472 to a bank of EDC syndrome generators 474 and to a bank of ECC syndrome generators 476. The outputs 478 of the EDC syndrome generators 474 are the values \tilde{c}_{EDC}(a) as a ranges over the set A. The outputs 480 of the ECC syndrome generator 476 are the values \tilde{c}_{ECC}(b) as b ranges over the set B. The set of EDC syndrome generators 474 typically consists of r syndrome generators of the type described in FIG. 7. The block 476 typically consists of s syndrome generators of the type described in FIG. 7, where the multiplier block 704 now implements multiplication by b. The computation of the EDC syndromes 478 is complete after the EDC syndrome generator 474 has read the symbol \tilde{p}₀. Thus, the computation of the EDC syndromes 478 takes r+k clock cycles and the s symbols \tilde{q}ⱼ are ignored for the purpose of EDC syndrome computation. Similarly, the computation of the ECC syndromes 480 is complete after the ECC syndrome generator 476 has read the symbol \tilde{q}₀, so that the computation of the ECC syndromes 480 takes r+s+k clock cycles.

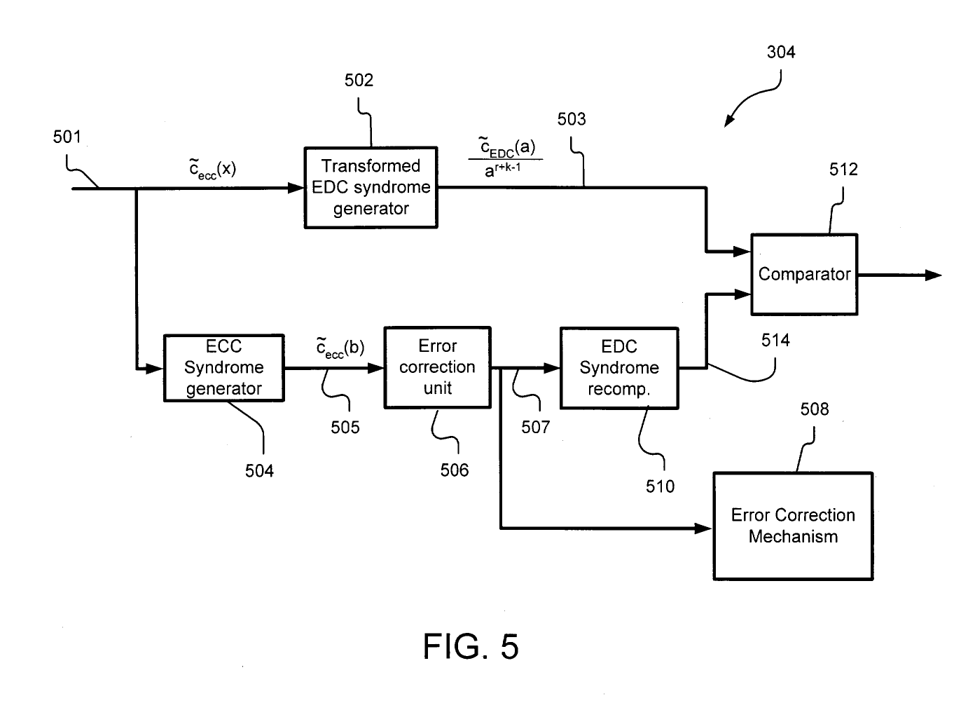

FIG. 5 is a module diagram illustrating primary functional modules of a decoder 304 shown in FIG. 3 in accordance with an embodiment of the present invention. Both a transformed EDC syndrome generator 502 and an ECC syndrome generator 504 receive retrieved data \tilde{c}_{ECC}(x) 501 as in FIG. 16. As before, the EDC syndromes are the values \tilde{c}_{EDC}(α) as α ranges over the set A. The transformed EDC syndromes are the values 503

$$\frac{{\tilde{c}}_{EDC} ( α )}{{α}^{r + k - 1}}$$

as α ranges over the set A , where r is the number of EDC parity symbols and k is the number of data symbols. Each transformed EDC syndrome is zero if and only if the corresponding EDC syndrome is zero. The transformed EDC syndrome generator 502 first computes the EDC syndromes \tilde{c}_{EDC}(α), then divides the syndromes by α^{r+k-1} and outputs the values 503. Details of a particular embodiment of the transformed EDC syndrome generator 502 are discussed in further detail below. As in FIG. 16, the ECC syndrome generator 504 computes ECC syndromes 505 \tilde{c}_{ECC}(β) as β ranges over the set B.

The ECC syndromes 505 are the inputs to an error correction unit 506, which computes error locations and error values 507 using algorithms well-known to those skilled in the art. Typically, the error correction unit 506 first computes an error locator polynomial Λ(x) and an error evaluator polynomial Ω(x) by applying a key equation solver such as the Berlekamp-Massey algorithm. Both of these polynomials have coefficients in the Galois field GF(2^{h}). Next a Chien search systematically checks each location in the received codeword to determine if an error has occurred in that location. The locations in the codeword correspond to a Galois field elements in such a way that a location with an error corresponds to a root of the equation Λ(x)=0. Thus, the Chien search finds error locations through an exhaustive search for the roots of the error locator polynomial. In one embodiment, the Chien search begins with the location occupied by the last ECC parity symbol q₀ and ends with the location occupied by the first data symbol dₖ₋₁. In this way, the retrieved data and parity symbols are checked for errors, one symbol per clock cycle, in the following order: \tilde{q}₀, . . . , \tilde{q}ₛ₋₁, \tilde{p}₀, . . . , \tilde{p}ᵣ₋₁, \tilde{d}₀, . . . , \tilde{d}ₖ₋₁. If an error is found in the symbol \tilde{d}ₙ, then the error value eₙ is determined by the equation \tilde{d}ₙ=dₙ+eₙ. Typically, the error value is computed from the error location, the error locator polynomial, and the error evaluator polynomial by applying Forney's algorithm. The particular manner in which the error locations and the error values are calculated is not particularly relevant to an embodiment of the present invention. Those skilled in the art are referred to “Error-Correction Coding for Digital Communications,” by Clark and Cain, for a more detailed discussion of error correction algorithms.

The error locations and error values 507 computed by the error correction unit 506 are sent to an error correction mechanism 508 that performs corrections on the retrieved user data. Typically, the user data have been stored in a buffer and for each correction computed by the error correction unit 506, the correction mechanism 508 will read the corrupted data symbol, perform the correction in the data, then write the corrected data back to the buffer. The details are not relevant to the present invention, as the purpose of the present invention is to validate, rather than calculate, an error correction.

The error locations and error values 507 are also sent to an EDC syndrome recomputation block 510, which recomputes the transformed EDC syndromes 511 from the error locations and values using Horner's algorithm in a manner to be described in more detail later. Finally, the transformed EDC syndromes 503 computed by the block 502 and the transformed EDC syndromes 511 computed by the recomputation block 510 are sent to a comparator 512 for comparison. If the two sets of syndromes are not equal, then a miscorrection has been detected. The comparator 512 preferably outputs a binary value, depending on the difference between the transformed EDC syndromes 503 and the transformed EDC syndromes 511. The comparator 512 is preferably implemented with combinational logic, such as computing the bitwise XOR of the two sets of syndromes and verifying the resulting bits are all zero. However, the comparator 512 may also be implemented in any combination of hardware, firmware, or software as suited to the particular implementation. In particular, the comparator 512 may include a tolerance value whereby if the transformed EDC syndromes 503 and the transformed EDC syndromes 511 differ only slightly (e.g. only by the tolerance value), the comparator 512 will nonetheless consider the values equal.

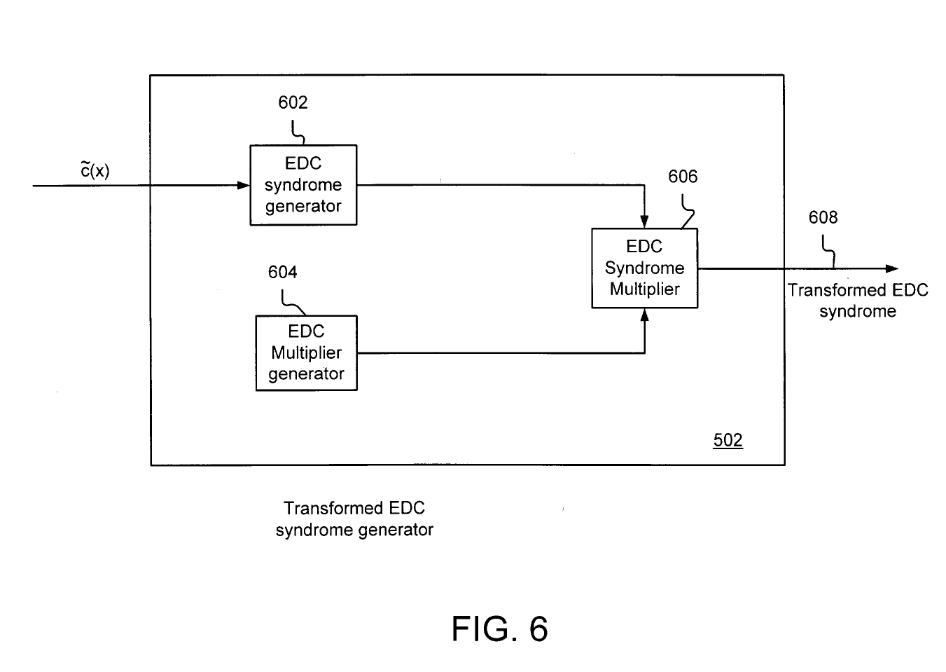

FIG. 6 illustrates one exemplary embodiment of a transformed error detection code (EDC) syndrome generator 502. The transformed EDC syndrome generator 502 includes a non-transformed EDC syndrome generator 602, an EDC multiplier generator 604 and an EDC syndrome multiplier 606. The EDC syndrome generator 602 calculates syndrome values associated with retrieved data \tilde{c}_{EDC}(x). As in FIG. 16, the EDC syndrome generator 602 calculates syndrome values \tilde{c}_{EDC}(a), as a ranges over the fixed set A. If any of the syndromes calculated by the EDC syndrome generator 602 are non-zero, an error has occurred in the retrieved EDC codeword \tilde{c}_{EDC}(x), and, hence, in the retrieved ECC codeword \tilde{c}_{ECC}(x). When the EDC syndrome generator 602 calculates syndrome values, the EDC multiplier generator 604 generates multiplier values in parallel.

The outputs of the EDC multiplier generator 604 are powers a^{-(r+k-1)} as a ranges over the fixed set A. Both the outputs c_{EDC}(a) of the EDC syndrome generator 602 and the outputs a^{-(r+k-1)} of the EDC multiplier generator 604 are communicated to the EDC syndrome multiplier 606. The EDC syndrome multiplier 606 multiplies the EDC syndromes with the EDC multipliers to yield the transformed EDC syndromes

$$\frac{{\tilde{c}}_{EDC} ( α )}{{α}^{r + k - 1}} .$$

The transformed EDC syndrome may be used as an indicator of errors in the retrieved data \tilde{c}ECC(x) or in a corrected version of \tilde{c}_{ECC}(x). During operation, the transformed EDC syndrome values are preferably stored in memory so that they can be used later to identify miscorrections, if any.

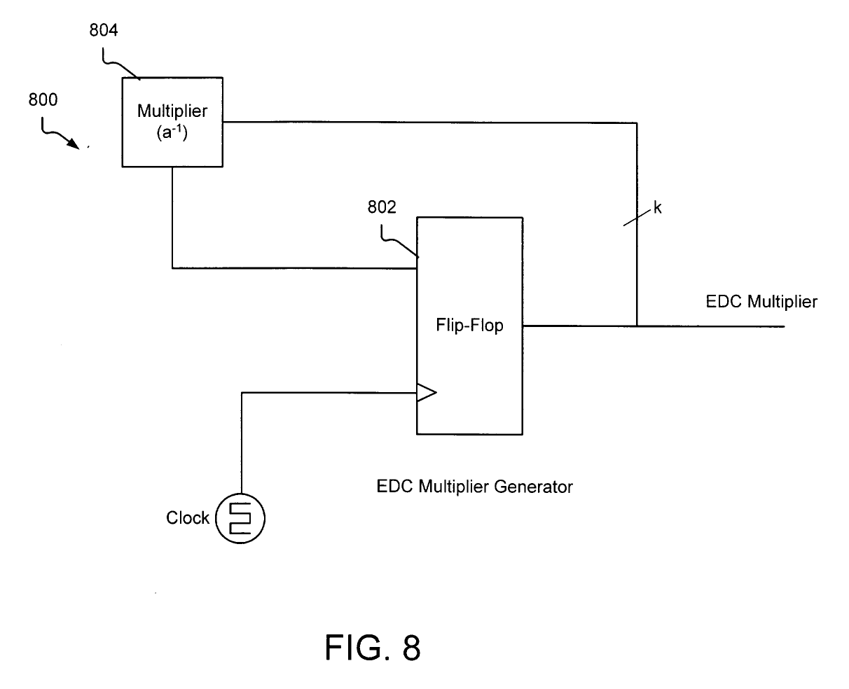

FIG. 8 illustrates a circuit diagram in accordance with an embodiment of the EDC multiplier generator 604 of FIG. 6. The circuit 800 includes a bank of flip-flops 802 and a multiplier 804 coupled together in a feedback relationship. The bits in the flip-flops 802 are initialized to a value corresponding to the element 1 in the Galois field GF(2^{h}). The bits in the flip-flops 802 are clocked out of the flip-flops 802 and input to the multiplier 804. The multiplier 804 multiplies the input by a fixed value a⁻¹. The output of the multiplier 804 is clocked into the flip-flop 802. After one clock cycle, the value in the flip-flops 802 equals 1·a⁻¹=a⁻¹. After two clock cycles, the value equals a⁻¹·a⁻¹=a⁻². After three clock cycles, the value equals a⁻²·a⁻¹=a⁻³, etc. Finally, after r+k−1 clock cycles, the value in the flip-flops 802 equals a^{-(r+k-1)}.

Now referring back to FIG. 5, the value of an EDC syndrome is \tilde{c}_{EDC}(α)=\tilde{d}ᵣ₋₁α^{r+k-1}+ . . . +\tilde{d}₀α^{r}+\tilde{p}ᵣ₋₁α^{r-1}+ . . . + [symbol] ₀, so that the value of the corresponding transformed EDC syndrome is

$$\frac{{\tilde{c}}_{EDC} ( α )}{{α}^{r + k - 1}} .$$

To simplify the notation, c_{EDC}(x) will be written as c(x), where c(x)=cᵣ₊ₖ₋₁x^{r+k-1}+ . . . +c₁x+c₀, so that cᵢ=pᵢ, for i=0, 1, . . . , r−1 and cᵢ=dᵢ₋ᵣ, for ii=r, r+1, . . . , r+k−1. Similarly, \tilde{c}_{EDC}(x) will be written as \tilde{c}(x), where \tilde{c}(x)=\tilde{c}ᵣ₊ₖ₋₁x^{r+k-}+ . . . +\tilde{c}₁x+\tilde{c}₀, so that \tilde{c}ᵢ=\tilde{p}ᵢ, for i=0, 1, . . . , r−1 and \tilde{c}ᵢ=\tilde{d}ᵢ₋ᵣ, for i=r, r+1, . . . , r+k−1. With this new notation, the EDC syndrome is \tilde{c}(a)=\tilde{c}ᵣ₊ₖ₋₁a^{r+k-}1+ . . . +\tilde{c}₁a+\tilde{c}₀ and the transformed EDC syndrome is

$$\frac{\tilde{c} ( α )}{{α}^{r + k - 1}} = {{\tilde{c}}_{0} ( {a}^{- 1} )}^{r + k - 1} + {{\tilde{c}}_{1} ( {a}^{- 1} )}^{r + k - 2} + ⋯ + {\tilde{c}}_{r + k - 2} ( {a}^{- 1} ) + {\tilde{c}}_{r + k - 1} .$$

In effect, the transformed EDC syndrome is \tilde{c}ᵣₑᵥ(a⁻¹), where \tilde{c}ᵣₑᵥ(x) is \tilde{c}(x) with the order of its coefficients reversed \tilde{c}ᵣₑᵥ(x)=\tilde{c}₀x^{r+k-1}+\tilde{c}₁x^{r+k-2}+ . . . +\tilde{c}ᵣ₊ₖ₋₂x+\tilde{c}ᵣ₊ₖ₋₁. The error in symbol i, computed by the error correction unit 506, will be denoted eᵢ, so that cᵢ+eᵢ=\tilde{c}ᵢ. Then if e(x)=eᵣ₊ₖ₋₁x^{r+k-1}+eᵣ₊ₖ₋₂x^{r+k-2}+ . . . +e₁x+e₀, then \tilde{c}(x)=c(x)+e(x) and \tilde{c}ᵣₑᵥ(x)=cᵣₑᵥ(x)+eᵣₑᵥ(x), where eᵣₑᵥ(x)=e₀x^{r+k-1}+e₁x^{r+k-2}+ . . . +eᵣ₊ₖ₋₂x+eᵣ₊ₖ₋₁. Therefore, the transformed EDC syndrome is \tilde{c}ᵣₑᵥ(a⁻¹)=\tilde{c}ᵣₑᵥ(a⁻¹)+eᵣₑᵥ(a⁻¹)=0+eᵣₑᵥ(a⁻¹)=eᵣₑᵥ(a⁻¹). The EDC syndrome recomputation block 510 will recompute the transformed EDC syndrome by evaluating the polynomial eᵣₑᵥ(x) at x=a⁻¹ by Horner's algorithm, using the error values determined by the error correction unit 506.

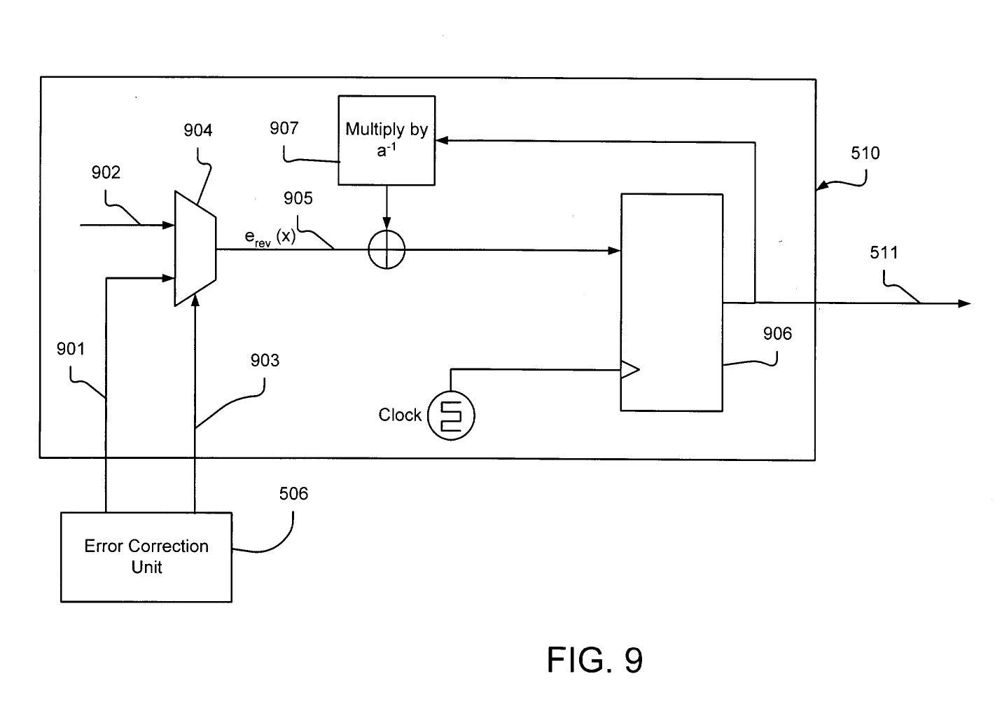

FIG. 9 illustrates a circuit implementing the EDC re-computation block 510 shown in FIG. 5. The part of the circuit containing the bank of flip-flops 906 and the block 907 implementing multiplication by a⁻¹ implements Horner's algorithm and functions like the circuit depicted in FIG. 7. The inputs 905 are the coefficients of the reversed error polynomial eᵣₑᵥ(x), which are transferred one symbol per clock cycle in the following order: e₀, e₁, . . . , eᵣ₊ₖ₋₂, eᵣ₊ₖ₋₁. The flip-flops 906 are initialized to zero and after the transfer of e₀ take on the value 0·a⁻¹+e₀=e₀. During the next cycle, e₁ is transferred along input line 905 and the value in the flip-flops 906 becomes e₀·a⁻¹+e₁. During the next cycle, e₂ is transferred along input line 905 and the value in the flip-flops 906 becomes (e₀·a⁻¹+e₁)·a⁻¹+e₂=e₀·(a⁻¹)²+e₁·a⁻¹+e₂. After the final coefficient eᵣ₊ₖ₋₁ has been transferred, the value in the flip-flops 906 is e₀(a⁻¹)^{r+k-1}+e₁(a⁻¹)^{r+k-2}+ . . . +eᵣ₊ₖ₋₂a⁻¹+eᵣ₊ₖ₋₁=eᵣₑᵥ(a⁻¹), which is the transformed EDC syndrome.

The error values eᵢ are the outputs of a multiplexor 904 which has two inputs: an error value 901 computed by the error correction unit 506 and an input 902 which is always zero. When the error correction unit 506 determines that there is an error in the i^{th} symbol \tilde{c}ᵢ, the corresponding error value eᵢ is transmitted on 901. In addition, the control signal 903 causes the value 901 to be output by the multiplexor 904 as its output 905. When the error correction unit 506 determines that there is not an error in the i^{th} symbol \tilde{c}ᵢ, the value eᵢ is zero and the control signal 903 causes the zero value 902 to be output by the multiplexor 904 as its output on line 905. In this case, it does not matter what the value 901 is.

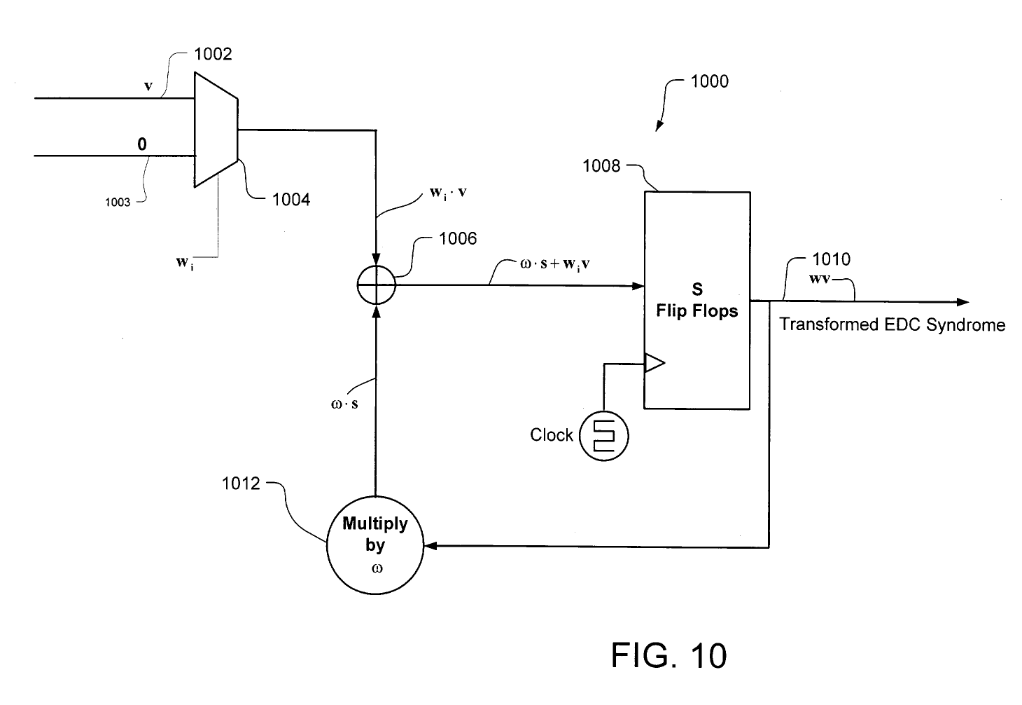

FIG. 10 illustrates a circuit diagram in accordance with an alternative embodiment of the EDC Syndrome multiplier 606 in FIG. 6 in accordance with the present invention. Recall that the multiplier 606 computes the product of a EDC syndrome \tilde{c}_{EDC}(α) with a power a^{-(r+k-1)} to produce the transformed EDC syndrome

$$\frac{{\tilde{c}}_{EDC} ( α )}{{α}^{r + k - 1}} .$$

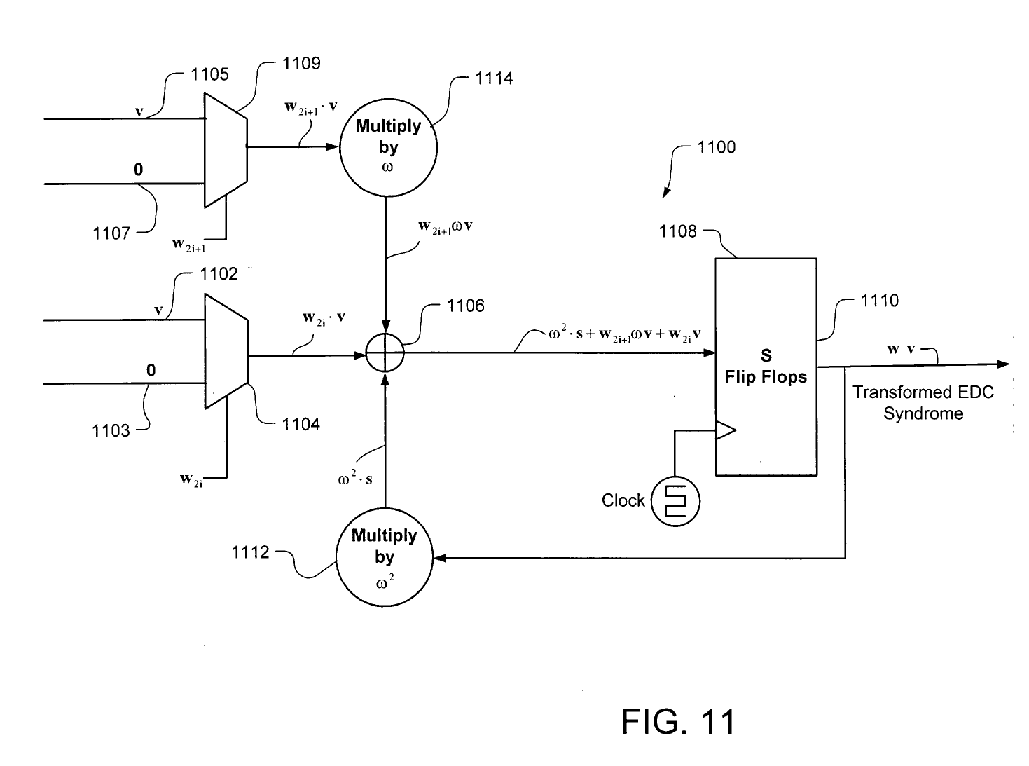

Since the two terms in the product are elements of the Galois field GF(2^{h}), the block 606 is often referred to as a Galois field multiplier. Typically, a Galois field multiplier will compute a product in one clock cycle. However, the circuit complexity of a Galois field multiplier can be reduced if the product can be computed over several clock cycles. In this alternative, since the corrupted ECC parity symbols, in FIG. 6, are processed over a number of clock cycles and the transformed EDC syndromes are not used until the ECC parity symbols have been processed, there is more time to compute the product which yields the transformed EDC syndrome. Therefore more cost-effective hardware may be utilized. Two approaches are shown in FIG. 10 and FIG. 11.

One way to represent an element w of GF(2^{h}) is as a polynomial wₕ₋₁ω^{h-1}+ . . . +w₁ω+w₀, where ω is a root of a degree h polynomial φ(x), whose coefficients are in GF(2) (i.e. each wᵢ is either 0 or 1) and which is irreducible over GF(2). Addition (resp. subtraction) is simply polynomial addition (resp. subtraction). In both cases, the operation amounts to bitwise XOR. Multiplication is polynomial multiplication followed by a reduction using the relationship φ(ω)=0. After this reduction, the product is again a polynomial in ω of degree no greater than h−1.

[John: in FIG. 10 change ‘a’ to ‘w’ and ‘γ’ to ‘v’. Sorry about the change, but ‘a’ has a specific meaning elsewhere in the patent application.]

Let v and w be elements of GF(2^{h}), where w=wₕ₋₁ω^{h-1}+ . . . +w₁ω+w₀. (Here v will be an EDC syndrome \tilde{c}_{EDC}(α) and w will be a power a^{-(r+k-1)} or vice versa.) The following method calculates the product wv over h clock cycles. In this case the method processes one of the h bits wᵢ per clock cycle, starting with wₕ₋₁ and ending with w₀.

Initially, S=0. In essence, each iteration replaces S by ω·S+wᵢ·v.

Iteration 1:

S=0; process wₕ₋₁

S=ω·S+wₕ₋₁·v=ω·0+wₕ₋₁=wₕ₋₁·v

Iteration 2:

S=wₕ₋₁·v, process wₕ₋₂

S=ω·s+wₕ₋₂·v=ω·(wₕ₋₁·v)+wₕ₋₂·v=(wₕ₋₁ω+wₕ₋₂)·v

Iteration 3:

S=(wₕ₋₁ω+wₕ₋₂)·v, process wₕ₋₃

S=α·S+wₕ₋₃·v=(wₕ₋₁107²+wₕ₋₂ω+wₕ₋₃)·v

●

●

●

Iteration h:

S=(wₕ₋₂ω^{h-2}+wₕ₋₃ω^{h-3}+ . . . +w₂ω+w₁)·v and process w₀_{⁰}.

S=(wₕ₋₁ω^{h-1}+wₕ₋₂ω^{h-2}+ . . . +w₁ω+w₀)·v=w·v

The transformed EDC syndrome multiplier circuit 1000 that embodies the above is shown in FIG. 10. This embodiment essentially is a circuit 1000 that implements a Horner evaluation. In essence, this circuit performs similar functions to that of EDC syndrome multiplier 606 in FIG. 6, except wv is computed over h clock cycles. Multiplexor 1004 receives the h bits of the v input on line 1002 and a 0 input on line 1003. The output of the multiplexor 1004 is controlled by the value of the bit wᵢ. If wᵢ is equal to 1, the output of the multiplexor 1004 is v. If wᵢ is equal to 0, the output of the multiplexor 1004 is 0. Thus, the output of multiplexor 1004 is really wᵢ·v. This output is fed to the adder 1006. The adder 1006 also receives an input from multiplier 1012 which is ω·S. Thus the output of the adder 1006 is ω·S+wᵢ·v, which becomes the new value of S in the bank of h flipflops 1008. The output S of the bank of flip flops 1008 is the input to the multiplier 1012, which in turn is multiplied by ω and fed to the adder 1006. After h clock cycles the summation output of the bank of flipflops 1008 is S=w·v. When w and v are chosen to be an EDC syndrome and a power of a (in some order) the output 1010 is the transformed EDC syndrome.

FIG. 11 illustrates a circuit diagram of another alternative embodiment of an EDC syndrome computer 1100 in accordance with the present invention that takes half the clock cycles to complete as does the alternative shown in FIG. 10. This embodiment essentially is a circuit 1100 that implements an accelerated Horner evaluation. Here, h is always even. Thus wv is computed over h/2 clock cycles and thus takes half the time to complete. The decreased computation time comes at the cost of more expensive hardware.

Initially, S=0. In essence, each iteration replaces S by ω²·S+(w₂ᵢ₊₁ω+w₂ᵢ)·v.

Iteration 1:

S=0; process wₕ₋₁ and wₕ₋₂

S=ω²·S+(wₕ₋₁ω+wₕ₋₂)·v=(wₕ₋₁ω+wₕ₋₂)·v

Iteration 2:

S=(wₕ₋₁ω+wₕ₋₂)·v, process wₕ₋₃ and wₕ₋₄

S=ω²·S+(wₕ₋₃ω+wₕ₋₄)·v=ω²·(wₕ₋₁ω+wₕ₋₂)·v+(wₕ₋₃ω+wₕ₋₄)·v

S=(wₕ₋₁ω³+wₕ₋₂ ω²w_{h-4)·}v

Iteration h/2:

S=(wₕ₋₁ω^{h-3}+wₕ₋₂ω^{h-4}+ . . . +w₃ω+w₂)·v, process w₁ and w₀

S=(wₕ₋₁ω^{h-1}+wₕ₋₂ω^{h-2}+ . . . +w₁ω+w₀)·v=w·v

The EDC syndrome generator circuit 1100 receives the same inputs on two multiplexors 1109 and 1104. The output of the multiplexor 1109 is w₂ᵢ₊ₗ·v, whereas the output of the multiplexor 1104 is w₂ᵢ·v. The output of multiplexor 1109 is fed to a multiplier 1114 which multiplies the input by ω and provides w₂ᵢ₊ₗω·v to the adder 1106. The output of multiplexor 1104, which is w₂ᵢ·v, is also provided to the adder 1106. As in the embodiment just described above, the adder also receives a feedback of the value S from the bank of h flip flops 1108, except that the feedback value S is fed through a multiplier 1112 which multiplies by ω². The output of the adder 1106 then is ω²·S+w₂ᵢ₊ₗω·v+w₂ᵢ·v, which subsequently becomes the value stored in the flip flops 1108. After h/2 clock cycles the value on the line 1110 is the transformed EDC syndrome w·v.

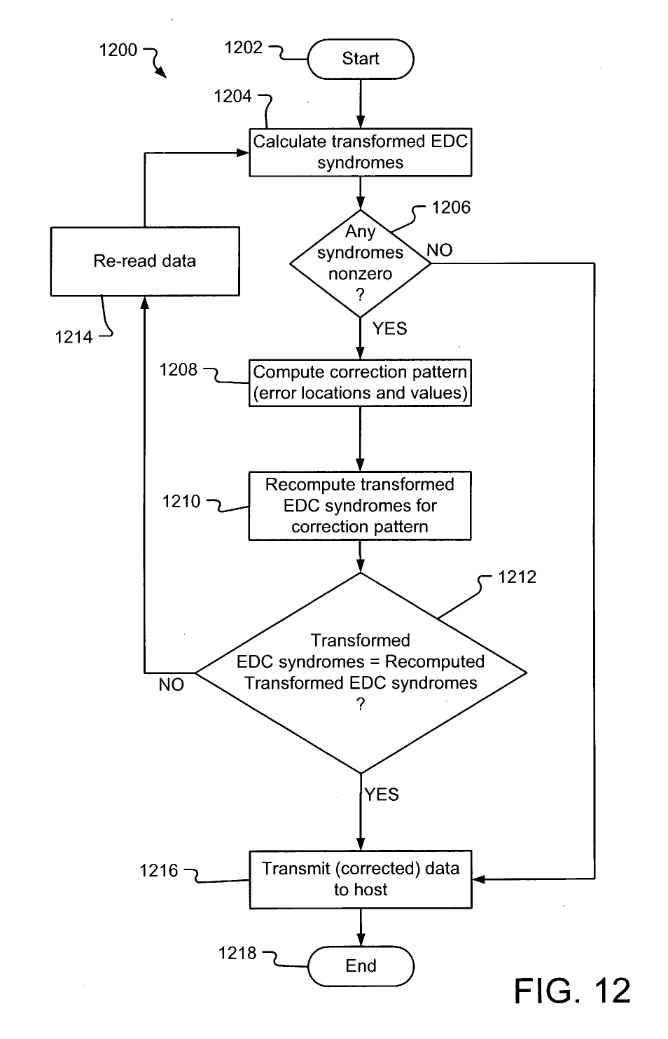

FIG. 12 illustrates an error detection operation 1200 having exemplary operations employed by an embodiment of an error detection system of the present invention. The embodiment illustrated in FIG. 12 is particularly suited for a disc drive; however, the operations illustrated may be easily adapted by one skilled in the art to any other data transfer system, including, but not limited to, a digital communication system. In the context of disc drive operation, the disc drive responds to commands from a host computer. Data may be read from the disc and transmitted to the host in response to the commands. Prior to transmitting the data to the host, the disc drive analyzes the data to determine if errors are present in the data. By way of example, but not limitation, the host may issue a read command to the disc drive. In response, the disc drive reads from a requested physical disc sector, and performs the error detection operation 1200.

In general, the error detection operation 1200 iteratively computes and compares transformed EDC syndromes to recomputed transformed EDC syndromes to determine whether data has been miscorrected. After a start operation 1202, a calculate operation 1204 calculates one or more transformed EDC syndrome values using a predetermined error detection algorithm. The error detection algorithm that is used is related to the algorithm used by the encoder to generate the error detection code. For example, if in one embodiment, the transformed EDC syndrome values are calculated by first calculating non-transformed EDC syndrome values and multiplying them by powers of values associated with the error detection algorithm, as discussed above. The transformed EDC syndrome values may be calculated as the data is read from the disc. The calculate operation 1204 may include various steps, such as a storing step, wherein transformed EDC syndromes are stored in memory for later comparison and analysis.

After the calculate operation 1204, a query operation 1206 determines if any of the previous calculated transformed EDC syndromes are non-zero. (In addition, ECC syndromes are examined. If these syndromes are also all zero, then it is know with greater certainty that no errors have occurred.) A non-zero transformed EDC syndrome value indicates an error the retrieved data. Thus, if any of the transformed EDC syndromes are determined to be non-zero, an error correction process is undertaken. If none of the transformed EDC syndromes are determined to be zero, the operation 1200 branches “NO” to a transmit operation 1214.

If the query operation 1206 determines that any of the transformed EDC syndrome values are non-zero, the error detection operation 1200 branches “YES” to a calculate operation 1208. The calculate operation calculates errors associated with the retrieved data and any corrected data. In one embodiment, the calculate operation 1208 creates a key equation solver to compute an error locator polynomial and an error evaluator polynomial. Those skilled in the art will be familiar with error locator polynomials and error evaluator polynomials. Using the error locator polynomial and the error evaluator polynomial, roots of these polynomials are determined. The roots of these polynomials indicate locations of errors, as well as values needed to correct the errors.

After the calculate operation 1208 a recomputation operation 1210 recomputes the transformed EDC syndromes from the computed correction pattern. As discussed herein, the recomputed transformed EDC syndromes are a function of the calculated error, wherein symbols of an error value are multiplied by powers of the primitive values associated with the error detection algorithm. If no miscorrections have occurred, the transformed error values should be substantially equal to the previously calculated transformed EDC syndromes (calculated in the calculate operation 1204). Thus, a query operation 1212 determines whether the transformed EDC syndromes equal the recomputed transformed EDC syndromes.

The query operation 1212 preferably obtains the previously calculated transformed EDC syndrome values from memory and compares them to the recomputed transformed EDC syndromes. In one embodiment, the query operation 1212 determines whether the difference between the transformed EDC syndrome value and the recomputed transformed EDC syndromes is less than a predetermined threshold.

If the query operation 1212 determines that the transformed EDC syndrome values are not substantially equal to the recomputed transformed EDC syndromes, the error detection operation 1200 branches “NO” to a re-reading operation 1214. The re-reading operation 1214 re-reads data from the disc. The re-reading operation 1214 may include a step of realigning the transducer head and the disc drive, or any other remedial action prior to reading the data. If the query operation 1212 determines that the transformed EDC syndromes are substantially equal to the recomputed transformed EDC syndromes, the error detection operation 1200 branches “YES” to the transmitting operation 1216. The transmitting operation 1216 transmits the data as it may have been corrected to the host. The error detection operation 1200 ends at end operation 1218.

The logical operations of the various embodiments of the present invention are implemented (1) as a sequence of computer implemented acts or program modules running on a computing system, such as the disc drive 100 (FIG. 1), and/or (2) as interconnected machine logic circuits or circuit modules within the computing system. The implementation is a matter of choice dependent on the performance requirements of the computing system implementing the invention. Accordingly, the logical operations making up the embodiments of the present invention described herein are referred to variously as operations, structural devices, acts or modules. It will be recognized by one skilled in the art that these operations, structural devices, acts and modules may be implemented in software, in firmware, in special purpose digital logic, and any combination thereof without deviating from the spirit and scope of the present invention as recited within the claims attached hereto.

It will be clear that the present invention is well adapted to attain the ends and advantages mentioned as well as those inherent therein. While a presently preferred embodiment has been described for purposes of this disclosure, various changes and modifications may be made which are well within the scope of the present invention.

For example, one embodiment employs an EDC defined over GF(2^{k}) and an ECC defined over GF(2^{m}), where k is not equal to m. In this embodiment, the simplest case is where k=2m. When k=2m, one EDC coding/decoding iteration is performed for every two ECC coding/decoding iterations.

In yet another embodiment, the ECC is an interleaved code, where the user data and EDC parity is divided into several sub-blocks, called interleaves, for the purpose of ECC encoding and error correction. With an interleaved code, error corrections are performed on an interleave by interleave basis. The computation of the EDC syndromes from the computed error values has a number of stages, one for each interleave. The specific implementation depends on the number of interleaves.

More particularly, these variations may include the following:

Different Representations of GF(2^{h})

In the description of the invention set forth above, both the EDC and ECC work with symbols in GF(2^{h}), i.e. h-bit blocks of data are “represented” as elements of a Galois field. This representation allows the definition of basic arithmetic operations on the h-bit blocks of data. Mathematically there are many different ways to represent h-bit blocks of data as elements of GF(2^{h}). Typically the bit vector (bₕ₋₁, . . . , b₀) is represented as the polynomial bₕ₋₁ω^{h-1}+ . . . +b₀, where ω satisfies a defining relationship φ(ω)=0 where φ(x) is an irreducible polynomial over GF(2). Here different irreducible polynomials will give different representations of the Galois field (with different definitions of the arithmetic operations). For example, GF(16) can be defined using any one of the following 3 defining relationships:

α⁴+α³+α²+α+1=0, α⁴+α³+1=0, or α⁴+α+1=0.

In a variation of the invention, the h-bit blocks of data can have one representation as elements of GF(2^{h}) for the purposes of EDC coding and another representation for the purposes of ECC coding.

Different Symbol Sizes

Another variation of the invention uses h-bit symbols for the EDC and g-bit symbols for the ECC, i.e. the EDC works with elements of GF(2^{h}) and the ECC works with elements of GF(2^{g}), where g≠h. The case where h=2 g is a special example. Here it is assumed that g bits of data are clocked on each clock cycle, so that 2 g bits of data are available every other clock cycle for the purposes of EDC encoding and decoding.

Interleaving

Another variation is an interleaved coding system in which the EDC works with 2 g-bit symbols and the ECC works with g-bit symbols. In the following description, the (possibly corrupted) g-bit symbols \tilde{x}ᵢ^{(j)} represent both ECC data and parity symbols read from the storage medium. The symbols are read from the medium in the following order: \tilde{x}ₙ⁽⁰⁾,\tilde{x}ₙ⁽¹⁾,\tilde{x}ₙ₋₁⁽⁰⁾,\tilde{x}ₓ₋₁⁽¹⁾, . . . , \tilde{x}₁⁽⁰⁾,\tilde{x}₁⁽¹⁾,\tilde{x}₀⁽⁰⁾,\tilde{x}₀⁽¹⁾. There are two ECC codewords: one consisting of the symbols in interleave 0 (where all elements have the superscript (0)) and the other consisting of the symbols in interleave 1 (where all elements have the superscript (1)). As above, the EDC works with 2 g-bit symbols.

Here the transformed EDC syndromes are of the form

(\tilde{x}₀₍₀₎&\tilde{x}₀⁽¹⁾)α⁻ⁿ+(\tilde{x}₁⁽⁰⁾&\tilde{x₁⁽¹⁾})α⁻⁽ⁿ⁻¹⁾+ . . . +(\tilde{x}ₙ₋₁⁽⁰⁾&\tilde{x}ₙ₋₁⁽¹⁾)α⁻¹+(\tilde{x}ₙ⁽⁰⁾&\tilde{x}ₙ ⁽¹⁾)

Such a syndrome can be written as the sum of two polynomial values:

((\tilde{x}₀⁽⁰⁾&0)α⁻ⁿ+(\tilde{x}₁⁽⁰⁾&0)α⁻⁽ⁿ⁻¹⁾+ . . . +(\tilde{x}ₙ₋₁⁽⁰⁾&0)α⁻¹+(\tilde{x}ₙ⁽⁰⁾&0))+(0&\tilde{x}₀^{(1))α}⁻ⁿ(0&\tilde{x}₁^{(1))α}⁻⁽ⁿ⁻¹⁾+ . . . +(0&\tilde{ₙ₋}1⁽¹⁾)α⁻¹+(0&\tilde{x}ₙ⁽¹⁾))

The formula for the transformed EDC syndrome remains valid when \tilde{x}^{(j)} is replaced by eᵢ^{(j)}, the computed error value in the same position as \tilde{x}ᵢ^{(j)}. Thus, the transformed EDC syndrome is equal to

(e₀⁽⁰⁾&0)α⁻ⁿ+(i e₁⁽⁰⁾&0)α⁻⁽ⁿ⁻¹⁾+ . . . +(eₙ₋₁⁽⁰⁾&0)α⁻⁽ⁿ⁻¹⁾+ . . . +(eₙ₋₁⁽⁰⁾&0)α⁻¹+(eₙ⁽⁰⁾&0))+(0&e₀⁽¹⁾α⁻ⁿ+(0&e₁⁽¹⁾)α⁻⁽ⁿ⁻¹⁾+ . . . +(0&eₙ₋₁⁽¹⁾)α⁻¹+(0&eₙ⁽¹⁾)).

The strategy for recomputing the transformed EDC syndrome using the error locations and values computed by the correction logic is as follows:

Use the standard hardware for Horner evaluation to compute polynomial values at α⁻¹.

As the error values eᵢ⁽⁰⁾ are computed for interleave 0, the inputs to the Horner evaluation circuit are (eᵢ⁽⁰⁾ & 0). When the first sum in the above formula has been computed, it is stored in a bank of flip-flops.

As the error values eᵢ⁽¹⁾ are computed for interleave 1, the inputs to the Horner evaluation circuit are (0 & eᵢ ⁽¹⁾). When the second sum in the above formula has been computed, it is XORed to (i.e. added to) the first sum to produce the transformed EDC syndrome.

Finally, the present invention may be implemented in any storage or communication device that employs an error-control coding algorithm based on Galois Fields. For example, the present invention may be implemented in a magnetic tape storage device. Numerous other changes may be made which will readily suggest themselves to those skilled in the art and which are encompassed in the spirit of the invention disclosed and as defined in the appended claims.

What is claimed is:

1. A method of detecting errors in transferred data comprising steps of:
receiving the transferred data having an error detection code appended to user data;
calculating a transformed error detection code syndrome;
calculating a recomputed error detection code syndrome;
comparing the recomputed transformed error detection code syndrome to the transformed error detection code syndrome; and
if the recomputed transformed error detection code syndrome corresponds to the transformed error detection code syndrome, transferring the data to a host.

2. The method of claim 1 further comprising steps of:
if the recomputed transformed error detection code syndrome does not correspond to the transformed error detection code syndrome, receiving the data again.

3. The method of claim 1, wherein the transformed error detection code syndrome recomputation step comprises steps of:
computing a correction pattern using a Chien search in conjunction with Forney's algorithm
recomputing the transformed error detection code syndrome using Horner's algorithm.

4. The method of claim 1, wherein the transformed error detection code syndrome calculating step comprises steps of:
generating an error detection code multiplier;
generating a non-transformed error detection code syndrome; and
multiplying the error detection code multiplier by the non-transformed error detection code syndrome.

6. The method of claim 1 wherein the step of calculating a recomputed transformed error detection code syndrome is performed only if the transformed EDC syndrome is nonzero.

7. The method of claim 6 wherein if the transformed EDC syndrome is zero, then the transmitted data is transmitted to the host.

8. A decoder comprising;
a transformed error detection code (EDC) syndrome generator receiving transferred data and producing a transformed error detection code syndrome;
a recomputed transformed error detection syndrome generator operable to generate a transformed error detection code syndrome associated with a computed correction pattern in the transferred data; and
a comparator coupled to the transformed EDC syndrome generator and the recomputed transformed error detection syndrome generator operable to compare the transformed error detection code syndrome to the recomputed transformed errordetection code syndrome.

9. The decoder of claim 8 further comprising:
an error locator operable to locate errors either in the transferred data or in a corrected version of the transferred data.

10. The decoder of claim 9, wherein the error locator is operable to perform a Chien search using the transferred data or the corrected version of the transferred data.

11. The decoder of claim 8, wherein the transformed EDC syndrome generator comprises:
a non-transformed EDC syndrome generator;
an EDC multiplier generator; and
an EDC syndrome multiplier coupled to the non-transformed EDC syndrome generator and the EDC multiplier generator wherein the EDC syndrome multiplier is operable to multiply the non-transformed EDC syndrome with the EDC multiplier to generate the transformed EDC syndrome.

12. The decoder of claim 11, wherein the non-transformed EDC syndrome generator comprises:
clocked flip-flops;
combinational logic coupled to an output of the flip-flops operable to multiply the output of the flip-flops with a value associated with the error detection code; and
a logical addition module receiving the transferred data and coupled to an output of the combinational logic operable to logically add the output of the combinational logic with the transferred data, the logical addition module coupled to an input of the flip-flop.

13. The decoder according to claim 8 further comprising an error correction code (ECC) syndrome generator connected to the comparator and receiving the transferred data.

14. The decoder according to claim 13 wherein the ECC syndrome generator is connected to the comparator through an error correction unit.

15. The decoder according to claim 14 wherein the error correction unit is connected to the comparator through an EDC syndrome recomparator.

16. The decoder according to claim 14 wherein the error correction unit is further connected to an error correction mechanism.

17. A data storage device comprising:
an error correction module in the device operable to correct errors in retrieved data retrieved from a data storage medium; and
means for determining whether the retrieved data has been miscorrected without recomputing an error detection code syndrome from the corrected data.

18. The data storage device according to claim 17 wherein the storage device is a disc drive.

19. The data storage device of claim 17, wherein the means for determining whether data has been miscorrected comprises:
a transformed error detection code (EDC) syndrome generator generating a transformed EDC syndrome;
a recomputed transformed error detection code syndrome generator; and
a comparator coupled to the transformed EDC syndrome generator operable to compare the generated transformed EDC syndrome to the recomputed transformed error detection syndrome to detect miscorrected data.

20. The device of claim 19 wherein the transformed EDC generator generates a transformed EDC syndrome in parallel with generation of the recomputed transformed error detection code syndrome by the recomputed transformed error detection code syndrome generator.

21. The device of claim 19, wherein the means for determining further comprises:
an error locator operable to identify error locations associated with corrected data;
an error evaluator operable to identify error values associated with error locations; and
wherein the recomputed transformed error detection code syndrome generator is operable to compute a polynomial value where the error values are the coefficients of the polynomial.
[John—do you need more details here?]

22. The device of claim 21, wherein the error locator comprises a Chien search engine and the error evaluator comprises a Forney's algorithm engine.

23. A method of detecting an error in error correction code (ECC) encoded data comprising steps of:
receiving ECC encoded data;
transforming the data in a transformed error detection code (EDC) syndrome generator into a transformed error detection code syndrome;
receiving the ECC encoded data in a recomputed transformed error detection syndrome generator;
generating a recomputed transformed error detection syndrome associated with a computed correction pattern in the ECC encoded data; and
comparing the transformed EDC syndrome with the recomputed transformed error detection syndrome.

24. The method of claim 23 further comprising a step of:
locating errors either in the received data using an error locator; and
correcting errors in the received data using an error evaluator.

25. The method of claim 24 wherein the locating step comprises performing a Chien search using the received data and the evaluating step comprises performing Forney's algorithm.

26. The method of claim 23, wherein the transforming step comprises:
generating a non-transformed EDC syndrome;
computing an EDC multiplier; and
multiplying the non-transformed EDC syndrome by the EDC multiplier to generate the transformed EDC syndrome.

27. The method of claim 26, wherein the step of generating a non-transformed EDC syndrome generator comprises:
receiving the data;
providing clocked flip-flops;
multiplying an output of the flip-flops with a value associated with the error detection code in the received data; and
logically adding the multiplied output to the received data.

28. The method of claim 23 further comprising steps of:
generating an error correction code (ECC) syndrome from the received data in an ECC syndrome generator.

29. The method of claim 28 wherein the ECC syndrome generator is connected to a comparator through an error correction unit.

30. The method of claim 29 wherein the error correction unit is connected to the comparator through an EDC syndrome recomparator.

31. A data communication system comprising:a data carrying medium;
a data transfer mechanism operably connected to the data carrying medium receiving data from the medium and sending data to the medium; and
an error correction module connected to the mechanism operable to correct errors in data received from the medium; and
means for determining whether received data has been miscorrected without recomputing an error detection code (EDC) syndrome from the corrected data.
